(19) United States
(12) Patent Application Publication
(10) Pub. No.: US 2010/0078730 A1
(43) Pub. Date: Apr. 1, 2010

(54) SEMICONDUCTOR DEVICE AND MANUFACTURING METHOD THEREOF

(75) Inventors: Yoichi YOSHIDA, Osaka (JP); Akihiko Tsuzumitani, Kyoto (JP); Kenshi Kanegae, Osaka (JP)

Correspondence Address: McDERMOTT WILL & EMERY LLP, 600 13th Street, N.W., Washington, DC, 20005-3096, US

(73) Assignee: PANASONIC CORPORATION, OSAKA (JP)

(21) Appl. No.: 12/633,486

(22) Filed: Dec. 8, 2009

Related U.S. Application Data
(63) Continuation of application No. PCT/JP2009/000231, filed on Jan. 22, 2009.

(30) Foreign Application Priority Data
Feb. 12, 2008 (JP) 2008-030982

(51) Int. Cl. H01L 27/092; H01L 21/762; H01L 29/772

(52) U.S. Cl. 257/369; 438/400; 257/213; 438/585; 257/E27.062; 257/E21.545; 257/E29.242

(57) ABSTRACT

A semiconductor device includes a gate electrode. The gate electrode includes a silicide layer obtained by siliciding porous silicon or organic silicon.

### CROSS-REFERENCE TO RELATED APPLICATION

This is a continuation of PCT International Application PCT/JP2009/000231 filed on Jan. 22, 2009, which claims priority to Japanese Patent Application No. 2008-030982 filed on Feb. 12, 2008. The disclosures of these applications including the specifications, the drawings, and the claims are hereby incorporated by reference in its entirety.

### BACKGROUND

The present disclosure relates to semiconductor devices such as Large Scale Integrated (LSI) Circuits and methods for fabricating the same.

In recent years, as advanced semiconductor processes, attention has been drawn to processes for forming Fully Silicided (FUSI) electrode structures and metal gate electrode structures to improve the performance of transistors.

A conventional method for forming a FUSI electrode structure will be described with reference to FIG. 18. FIG. 18 is a cross-sectional view of a transistor having a conventional, general FUSI electrode structure. First, a polysilicon gate electrode is formed over a semiconductor substrate 1 with a gate oxide film 2 interposed therebetween, and then a sidewall insulating film 4 is formed on sidewalls of the polysilicon gate electrode. After that, source/drain regions 6 are formed thorough ion implantation using the polysilicon gate electrode and the sidewall insulating film 4 as a mask. Then, a refractory metal film is deposited over the semiconductor substrate 1 to cover the polysilicon gate electrode, and then annealed so that the polysilicon gate electrode is completely silicided (Fully Silicided) to form a FUSI gate electrode 3a and to form a silicide layer 7a in surface portions of the source/drain regions 6.

With the FUSI electrode structure, depletion of gate electrodes, which has been a problem of polysilicon gate electrodes, can be suppressed, which allows an ON current of the transistor to be increased.

Further, processes in which stress is controlled to improve the performance of transistors are employed. An example of such processes is a conventional method using a liner nitride film (stress liner film) described with reference to FIG. 19. FIG. 19 is a cross-sectional view schematically showing a structure of a transistor in which a conventional stress liner film is used to apply stress to the channel region of the transistor to improve carrier mobility. First, a polysilicon gate electrode 13 is formed over an active region surrounded by an insulative isolation region 12 in a silicon substrate 11. Next, on both of side surfaces of the polysilicon gate electrode 13, sidewall spacers (not shown) are formed with an offset spacer 14 and an oxide layer 15 interposed between each sidewall spacer and each side surface of the polysilicon gate electrode 13. Then, through ion implantation using the polysilicon gate electrode 13, the offset spacers 14, and the sidewall spacers as a mask, a pair of source/drain regions 17 are formed in portions of the silicon substrate 11 located on both side of the polysilicon gate electrode 13. Then, a silicide layer 18 is formed in the upper portions of the polysilicon gate electrode 13 and the source/drain regions 17, and then the sidewall spacers are removed. After that, a stress liner nitride film 19 is formed to cover the polysilicon gate electrode 13.

PATENT DOCUMENT 1: Japanese Patent Publication No. 2006-261282 (in particular, FIG. 1)

PATENT DOCUMENT 2: Japanese Patent Publication No. 2007-049166 (in particular, FIG. 1B)

NON-DOCUMENT 1: Tatsuya Shimoda et al., Solution-processed silicon films and transistors, Nature 440, Apr. 6, 2006, pp. 783-786

### SUMMARY

However, in devices including the above-described FUSI electrode and in methods using the liner nitride film to control stress, the inventors has observed the following problems.

When FUSI electrodes formed by fully siliciding polysilicon are used as gate electrodes of an N-channel transistor and a P-channel transistor, tensile stress is applied to the N-channel transistor due to expansion of its electrode during the silicidation, thereby improving the performance of the N-channel transistor. However, similar tensile stress is applied to the P-channel transistor, which may hinder improvement in performance of the P-channel transistor.

For the methods using the liner nitride film deposited to cover transistors for controlling the stress of the transistors, the thickness of the liner nitride film should be as large as possible in order to improve the effect of the stress of the liner nitride film. However, if the thickness of the liner nitride film is large, the thickness of the liner nitride film formed on the sidewall spacers on the side surfaces of the gate electrodes and between the gate electrodes may be larger than the thickness thereof on the other parts. This may cause the manufacturing problem that forming contacts becomes significantly difficult as the transistors are miniaturized. Moreover, if the thickness of the liner nitride film is large, problems such as crystal defects which are critical for the devices may be caused by cracks in the liner nitride film.

In view of the above-discussed problems, the present disclosure may be able to provide a semiconductor device in which stress can be controlled even in the case of miniaturizing the device, and a method for fabricating the same. In particular, according to the present disclosure, even when a semiconductor device including a gate electrode having a silicide layer is miniaturized, it may be possible to control stress in order to improve the performance of transistors.

For the above purposes, the inventors of the present application developed a semiconductor device in which volume expansion during silicidation of a gate electrode of a P-channel transistor is suppressed to allows stress in the gate electrode to be controlled, and a method for fabricating the same.

That is, a first semiconductor device according to the present disclosure includes a gate electrode including a silicide layer obtained by siliciding porous silicon or organic silicon.

According to the first semiconductor device of the present disclosure, as the gate electrode of the P-channel transistor, a gate electrode having a silicide layer obtained by siliciding porous silicon or organic silicon which is lower in density than ordinary silicon is used, so that volume expansion of the material for the gate electrode during silicidation can be suppressed. Therefore, tensile stress can be prevented from being applied to the P-channel transistor, which allows the performance of the P-channel transistor to be improved. That is, even in the case of miniaturizing the device, controlling the stress in the gate electrode can improve the performance of the P-channel transistor in a FUSI gate process or other processes. Moreover, the stress can be controlled without using a thick liner nitride film, so that the occurrence of problems such as crystal defects caused by cracks in the liner nitride film, which are critical for the devices, can be prevented, and so that contacts can be easily formed in the periphery of the gate electrode. Note that it is possible to simultaneously use a liner nitride film whose thickness or stress is sufficiently small or low so that no cracks occur.

Moreover, a second semiconductor device according to the present disclosure includes: an N-channel transistor; and a P-channel transistor, wherein the N-channel transistor includes a first gate electrode having a first silicide layer, the P-channel transistor includes a second gate electrode having a second silicide layer, the first silicide layer is formed by siliciding a first silicon-containing material, the second silicide layer is formed by siliciding a second silicon-containing material which is different from the first silicon-containing material, and a density of the second silicon-containing material is smaller than a density of the first silicon-containing material.

According to the second semiconductor device of the present disclosure, a silicon-containing material (e.g., porous silicon or organic silicon) which is lower in density than a silicon-containing material (e.g., silicon) for forming the silicide layer of the gate electrode of the N-channel transistor is used to form the silicide layer of the gate electrode of the P-channel transistor. Therefore, tensile stress caused by expansion of the electrode during silicidation can be sufficiently applied to the N-channel transistor, which allows the performance of the N-channel transistor to be improved. On the other hand, it is possible to prevent such tensile stress from being applied to the P-channel transistor, which allows the performance of the P-channel transistor to be improved. That is, even in the case of miniaturizing the device, controlling the stress in the gate electrode can improve the performance of the P-channel transistor and the N-channel transistor in a FUSI gate process or other processes. Moreover, the stress can be controlled without using a thick liner nitride film, so that the occurrence of problems such as crystal defects caused by cracks in the liner nitride film, which are critical for the devices, can be prevented, and so that contacts can be easily formed in the periphery of the gate electrode. Note that it is possible to simultaneously use a liner nitride film whose thickness or stress is sufficiently small or low so that no cracks occur.

Moreover, a method for fabricating a semiconductor device including a first transistor including a first gate electrode having a first silicide layer, and a second transistor including a second gate electrode having a second silicide layer includes: (a) forming an insulative isolation region on a semiconductor substrate to separate a first transistor region from a second transistor region; (b) forming a first silicon-containing material film over the semiconductor substrate, and then patterning the first silicon-containing material film over each of the first transistor region and the second transistor region into a gate electrode form; (c) forming an insulating film over the semiconductor substrate to cover all parts except an upper surface of the patterned first silicon-containing material film; (d) removing the patterned first silicon-containing material film over the second transistor region to form an opening; (e) in the opening, forming a second silicon-containing material film which has a density different from a density of the first silicon-containing material film; and (f) siliciding the patterned first silicon-containing material film over the first transistor region to form the first silicide layer, and siliciding the second silicon-containing material film formed in the opening to form the second silicide layer.

Specifically, in the method for fabricating the semiconductor device of the present disclosure, the first transistor is an N-channel transistor, the second transistor is a P-channel transistor, and the density of the second silicon-containing material film is smaller than the density of the first silicon-containing material film. In this case, the first silicon-containing material film is made of, for example, silicon, and the second silicon-containing material film is made of, for example, porous silicon or organic silicon.

Alternatively, in the method for fabricating the semiconductor device of the present disclosure, the first transistor is a P-channel transistor, the second transistor is an N-channel transistor, and the density of the first silicon-containing material film is smaller than the density of the second silicon-containing material film. In this case, the first silicon-containing material film is made of, for example, porous silicon or organic silicon, and the second silicon-containing material film is made of, for example, silicon.

That is, according to the method for fabricating the semiconductor device of the present disclosure, in order to form the silicide layers of the gate electrodes of the N-channel transistor and the P-channel transistor, a common silicon-containing material, for example, polysilicon is not used, but for the silicide layer of the gate electrode of the N-channel transistor, for example, ordinary polysilicon is used, whereas for the silicide layer of the gate electrode of the P-channel transistor, a silicon-containing material having a density lower than that of the N-channel transistor, for example, porous silicon or organic silicon is used. Therefore, tensile stress caused by volume expansion of the silicon-containing material during silicidation can be sufficiently applied to the N-channel transistor, which allows the performance of the N-channel transistor to be improved. On the other hand, it is possible to suppress such tensile stress caused by volume expansion of the silicon-containing material during silicidation from being applied to the P-channel transistor, which allows the performance of the P-channel transistor to be improved. That is, even in the case of miniaturizing the device, controlling the stress in the gate electrode can improve the performance of the P-channel transistor and the N-channel transistor in a FUSI gate process or other processes. Moreover, the stress can be controlled without using a thick liner nitride film, so that the occurrence of problems such as crystal defects caused by cracks in the liner nitride film, which are critical for the devices, can be prevented, and so that contacts can be easily formed in the periphery of the gate electrode. Note that it is possible to simultaneously use a liner nitride film whose thickness or stress is sufficiently small or low so that no cracks occur.

In the method for fabricating the semiconductor device of the present disclosure, the second gate electrode preferably includes a metal layer formed under the second silicide layer, and the method further includes, between (d) and (e), (g) forming the metal layer at least at a bottom of the opening. In this way, the threshold voltage (Vt) of the transistor can be controlled easily.

In the method for fabricating the semiconductor device of the present disclosure, the first transistor may include a first gate insulating film under the first gate electrode, the second transistor may include a second gate insulating film under the second gate electrode, and the method may further include, between (a) and (b), (h) forming the first gate insulating film and the second gate insulating film. In this way, the processes can be facilitated.

In the method for fabricating the semiconductor device of the present disclosure, the first transistor may include a first gate insulating film under the first gate electrode, the second transistor may include a second gate insulating film under the second gate electrode, the method may further include, between (a) and (b), (i) forming the first gate insulating film, and between (d) and (e), (j) forming the second gate insulating film at least at a bottom of the opening. In this method, unlike the case of previously forming the gate insulating film before forming the gate electrode, the gate insulating film is not damaged at (d), that is, in removing the patterned first silicon-containing material film over the second transistor region to form the opening. Therefore, it is possible to improve the reliability of the transistor. In this case, when the second gate electrode includes a metal layer formed under the second silicide layer, and the method further includes, between (j) and (e), (k) forming the metal layer on the second gate insulating film in the opening, the threshold voltage (Vt) of the transistor can be controlled easily.

In the method for fabricating the semiconductor device of the present disclosure, at least one of the first gate insulating film and the second gate insulating film may include a high-dielectric-constant insulating film. In this way, the physical thickness of the gate insulating film can be increased while reducing the equivalent oxide thickness thereof, which allows the performance of the transistor to be increased while suppressing its leak current.

A third semiconductor device according to the present disclosure includes a gate electrode, wherein the gate electrode includes a silicon layer made of porous silicon or organic silicon, and a silicide layer formed on the silicon layer.

That is, the third semiconductor device of the present disclosure has a configuration in which a silicon layer made of porous silicon or organic silicon remains under the silicide layer obtained by siliciding porous silicon or organic silicon in the configuration of the first semiconductor device of the present disclosure. Therefore, it is possible to achieve an effect similar to that of the first semiconductor device of the present disclosure.

In the third semiconductor device of the present disclosure, the gate electrode may further include a metal layer formed under the silicon layer. With this configuration, depletion of the gate electrode can be suppressed, and thus it is possible to increase an ON current of the transistor, which allows the operating speed of the integrated circuit to be improved.

A fourth semiconductor device according to the present disclosure includes a gate electrode having a silicide layer containing an organic substance.

That is, the fourth semiconductor device of the present disclosure corresponds in particular, to the configuration including the silicide layer obtained by siliciding organic silicon among configurations of the first semiconductor device of the present disclosure. Therefore, it is possible to achieve an effect similar to that of the first semiconductor device of the present disclosure.

As described above, according to the present disclosure, volume expansion during silicidation of the gate electrode of the P-channel transistor is selectively controlled, so that stress in the gate electrode can be controlled, which allows the performance of the transistor to be improved by controlling the stress even in the case of miniaturizing the device.

### BRIEF DESCRIPTION OF THE DRAWINGS

FIG. 1 is a cross-sectional view showing a structure of a semiconductor device according to Embodiment 1 of the present disclosure.

FIGS. 2A-2C are cross-sectional views showing processes in a method for fabricating the semiconductor device according to Embodiment 1 of the present disclosure.

FIGS. 3A-3C are cross-sectional views showing processes in the method for fabricating the semiconductor device according to Embodiment 1 of the present disclosure.

FIGS. 4A-4C are cross-sectional views showing processes in the method for fabricating the semiconductor device according to Embodiment 1 of the present disclosure.

FIGS. 5A-5C are cross-sectional views showing processes in the method for fabricating the semiconductor device according to Embodiment 1 of the present disclosure.

FIGS. 6A-6C are cross-sectional views showing processes in the method for fabricating the semiconductor device according to Embodiment 1 of the present disclosure.

FIGS. 7A-7C are cross-sectional views showing processes in the method for fabricating the semiconductor device according to Embodiment 1 of the present disclosure.

FIGS. 8A and 8B are cross-sectional views showing processes in the method for fabricating the semiconductor device according to Embodiment 1 of the present disclosure.

FIG. 9 is a cross-sectional view showing a structure of a semiconductor device according to Embodiment 2 of the present disclosure.

FIGS. 10A-10C are cross-sectional views showing processes in a method for fabricating the semiconductor device according to Embodiment 2 of the present disclosure.

FIGS. 11A-11C are cross-sectional views showing processes in a method for fabricating the semiconductor device according to Embodiment 2 of the present disclosure.

FIG. 12 is a cross-sectional view showing a structure of a semiconductor device according to Embodiment 3 of the present disclosure.

FIGS. 13A-13C are cross-sectional views showing processes in a method for fabricating the semiconductor device according to Embodiment 3 of the present disclosure.

FIGS. 14A-14C are cross-sectional views showing processes in a method for fabricating the semiconductor device according to Embodiment 3 of the present disclosure.

FIG. 15 is a cross-sectional view showing a structure of a semiconductor device according to Embodiment 4 of the present disclosure.

FIGS. 16A-16C are cross-sectional views showing processes in a method for fabricating the semiconductor device according to Embodiment 4 of the present disclosure.

FIGS. 17A-17C are cross-sectional views showing processes in a method for fabricating the semiconductor device according to Embodiment 4 of the present disclosure.

FIG. 18 is a cross-sectional view showing a structure of a gate electrode and its periphery in a semiconductor device including a FUSI electrode structure formed by a conventional method.

FIG. 19 is a cross-sectional view showing a structure of a gate electrode and its periphery in a semiconductor device including a liner nitride film formed by a conventional method.

FIGS. 20A and 20B are cross-sectional views showing processes in a method for fabricating a semiconductor device according to a first variation of Embodiment 1 of the present disclosure.

FIG. 21 is a cross-sectional view showing a process in the method for fabricating the semiconductor device according to the first variation of Embodiment 1 of the present disclosure.

FIGS. 22A and 22B are cross-sectional views showing processes in the method for fabricating the semiconductor device according to the first variation of Embodiment 1 of the present disclosure.

FIG. 23 is a cross-sectional view showing a structure of a semiconductor device according to a second variation of Embodiment 1 of the present disclosure.

FIGS. 24A and 24B are cross-sectional views showing processes in the method for fabricating the semiconductor device according to the second variation of Embodiment 1 of the present disclosure.

FIGS. 25A and 25B are cross-sectional views showing processes in the method for fabricating the semiconductor device according to the second variation of Embodiment 1 of the present disclosure.

FIGS. 26A and 26B are cross-sectional views showing processes in the method for fabricating the semiconductor device according to the second variation of Embodiment 1 of the present disclosure.

FIG. 27 is a cross-sectional view showing a structure of a semiconductor device according to a first variation of Embodiment 2 of the present disclosure.

FIG. 28 is a cross-sectional view showing a structure of the semiconductor device according to the first variation of Embodiment 2 of the present disclosure.

FIG. 29 is a cross-sectional view showing a structure of a semiconductor device according to a second variation of Embodiment 2 of the present disclosure.

FIG. 30 is a cross-sectional view showing a structure of the semiconductor device according to the second variation of Embodiment 2 of the present disclosure.

FIG. 31 is a cross-sectional view showing a structure of a semiconductor device according to a first variation of Embodiment 3 of the present disclosure.

FIG. 32 is a cross-sectional view showing a structure of the semiconductor device according to the first variation of Embodiment 3 of the present disclosure.

FIG. 33 is a cross-sectional view showing a structure of a semiconductor device according to a second variation of Embodiment 3 of the present disclosure.

FIG. 34 is a cross-sectional view showing a structure of the semiconductor device according to the second variation of Embodiment 3 of the present disclosure.

FIG. 35 is a cross-sectional view showing a structure of a semiconductor device according to a first variation of the Embodiment 4 of the present disclosure.

FIG. 36 is a cross-sectional view showing a structure of the semiconductor device according to the first variation of the Embodiment 4 of the present disclosure.

FIG. 37 is a cross-sectional view showing a structure of a semiconductor device according to a second variation of Embodiment 4 of the present disclosure.

FIG. 38 is a cross-sectional view showing a structure of the semiconductor device according to the second variation of Embodiment 4 of the present disclosure.

### DETAILED DESCRIPTION

### Embodiment 1

A semiconductor device according to Embodiment 1 of the present disclosure and a method for fabricating the same will be described below with reference to the drawings.

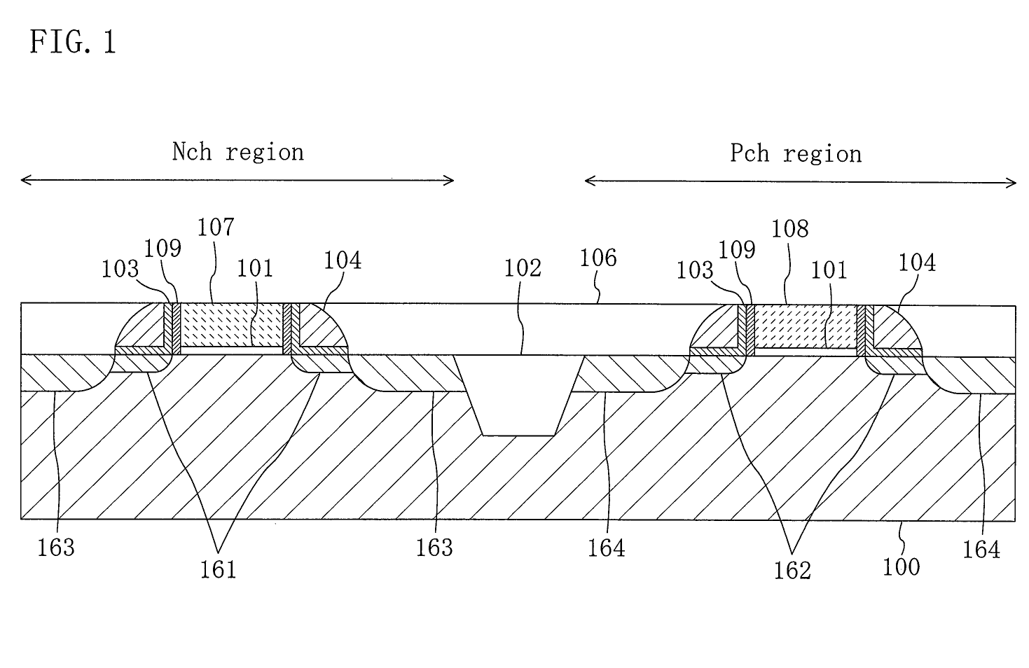

FIG. 1 is a cross-sectional view showing a structure of the semiconductor device according to Embodiment 1 of the present disclosure.

As shown in FIG. 1, an insulative isolation region 102 is provided on a semiconductor substrate 100 to separate an N-channel transistor region from a P-channel transistor region. The semiconductor substrate 100 is a silicon substrate whose principal plane is, for example, the (100) plane. A first FUSI electrode 107 is provided over the N-channel transistor region with a gate insulating film 101 interposed therebetween, and a second FUSI electrode 108 is provided over the P-channel transistor region with the gate insulating film 101 interposed therebetween. Offset spacers 109, a sidewall oxide film 103, and a sidewall nitride film 104 are sequentially provided on side surfaces of the first FUSI electrode 107 and the second FUSI electrode 108. Source/drain extension regions 161 are provided in surface portions of the semiconductor substrate 100 located under the sidewall films of the first FUSI electrode 107, and source/drain extension regions 162 are provided in surface portions of the semiconductor substrate 100 located under the sidewall films of the second FUSI electrode 108. Moreover, source/drain regions 163 are provided in surface portions of the semiconductor substrate 100 located outside the sidewall films of the first FUSI electrode 107, and source/drain regions 164 are provided in surface portions of the semiconductor substrate 100 located outside the sidewall films of the second FUSI electrode 108. Furthermore, an insulating film 106 which is, for example, a silicon oxide film is provided to cover the semiconductor substrate 100 except upper surfaces of the first FUSI electrode 107 and the second FUSI electrode 108.

A feature of the present embodiment is that the second FUSI electrode 108 of the P-channel transistor is formed by siliciding a silicon-containing material having a density lower than that of a silicon-containing material for forming the first FUSI electrode 107 of the N-channel transistor. Specifically, the first FUSI electrode 107 of the N-channel transistor is formed by siliciding ordinary polysilicon, whereas the second FUSI electrode 108 of the P-channel transistor is formed by siliciding porous silicon or organic silicon.

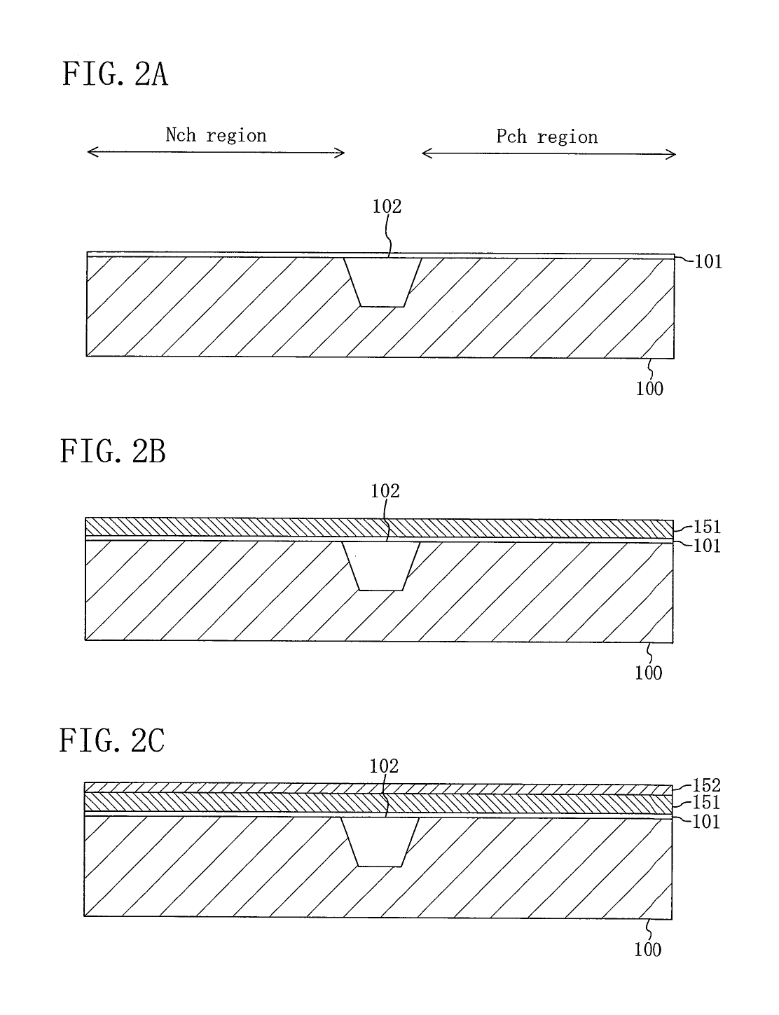

FIGS. 2A-2C, FIGS. 3A-3C, FIGS. 4A-4C, FIGS. 5A-5C, FIGS. 6A-6C, FIGS. 7A-7C, and FIGS. 8A and 8B are cross-sectional views showing processes in a method for fabricating the semiconductor device according to Embodiment 1.

First, as shown in FIG. 2A, on a semiconductor substrate 100 which is a silicon substrate whose principal plane is, for example, the (100) plane, an insulative isolation region 102 is formed to separate an N-channel transistor region from a P-channel transistor region. After that, a well region (not shown) is formed in each of the transistor regions. Next, a gate insulating film 101 which is, for example, a silicon oxide film is formed on the semiconductor substrate 100 including over the transistor regions.

Next, as shown in FIG. 2B, a first silicon-containing material film 151 which is, for example, a polysilicon film having a thickness of about 30 to 100 nm is deposited on the gate insulating film 101 by using, for example, a low-pressure chemical vapor deposition (CVD) apparatus or the like. The first silicon-containing material film 151 is deposited under such conditions that the temperature is, for example, 500 to 620° C., and the pressure is 0.5 to 5 Ton (66.5 to 665 Pa). Next, as shown in FIG. 2C, a hard mask film 152 having, for example, a thickness of about 30 to 100 nm is formed on the first silicon-containing material film 151 by using, for example, a vertical-type batch furnace or the like.

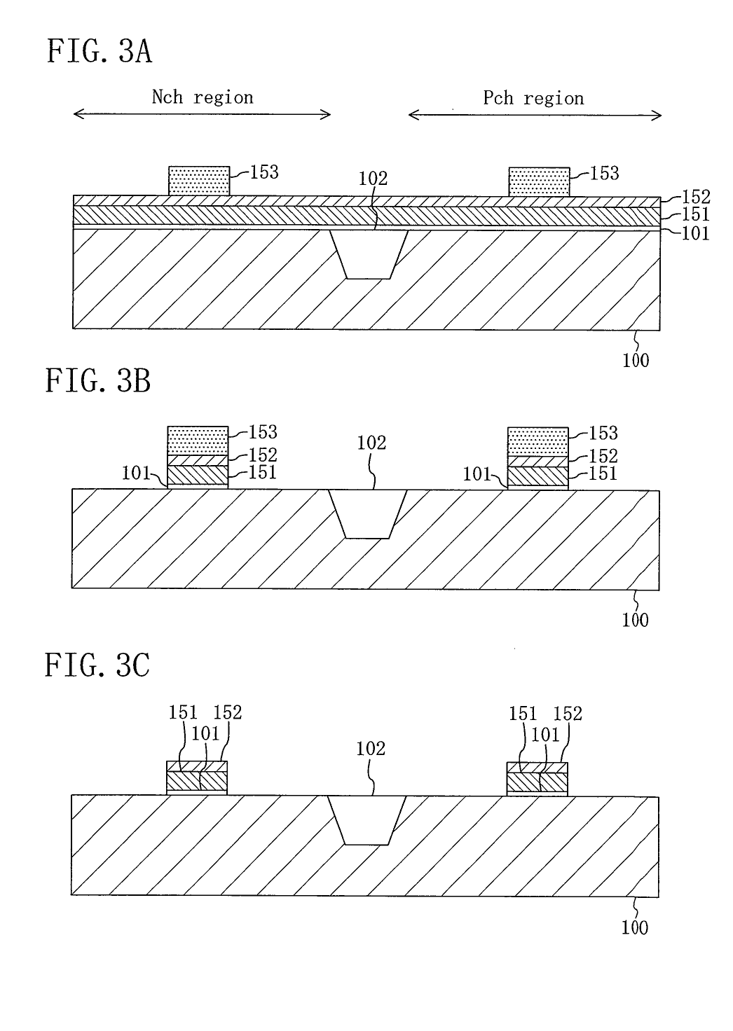

Next, as shown in FIG. 3A, on the hard mask film 152, a resist mask 153 covering a gate-electrode-formation region of each of the N-channel transistor region and the P-channel transistor region is formed. After that, as shown in FIG. 3B, the hard mask film 152, the first silicon-containing material film 151, and the gate insulating film 101 are anisotropically dry etched using the resist mask 153. In this way, the first silicon-containing material film 151 outside the resist mask 153 is removed, thereby patterning the first silicon-containing material film 151 into a gate electrode form. After that, as shown in FIG. 3C, the resist mask 153 is removed by cleaning with a liquid mixture of, for example, a sulfuric acid and aqueous hydrogen peroxide.

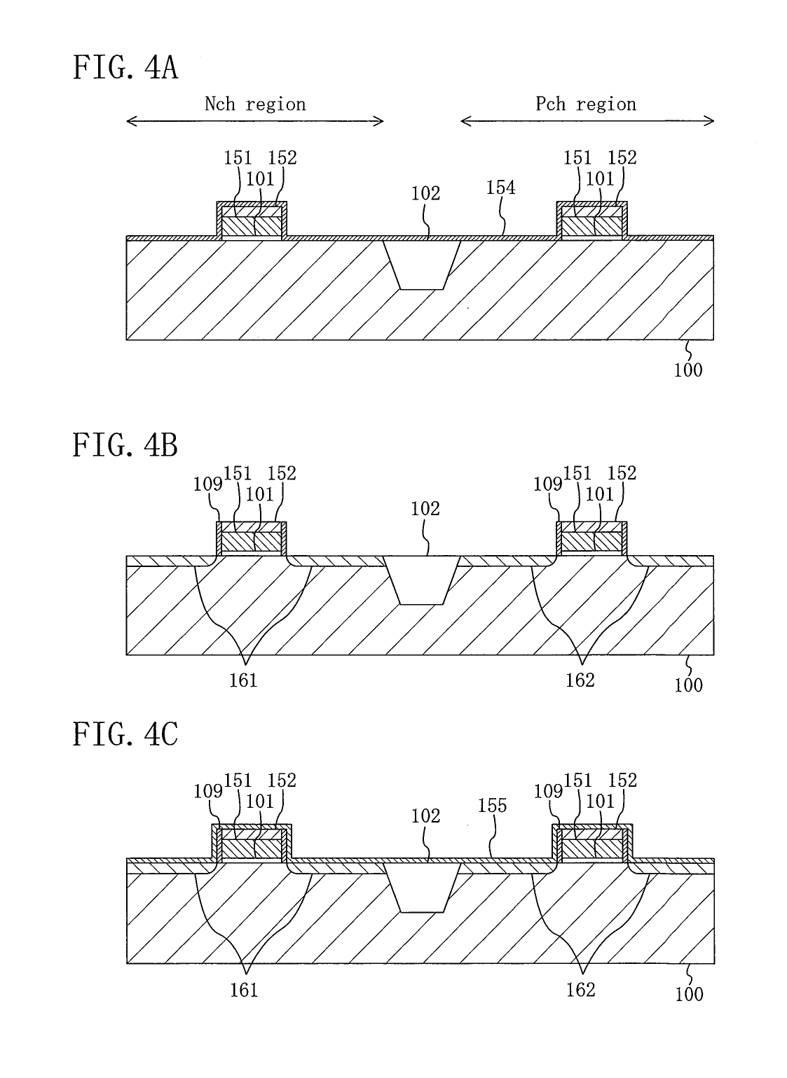

Next, as shown in FIG. 4A, a silicon oxide film 154 having, for example, a thickness of about 10 to 20 nm is formed over the entire surface including over the patterned first silicon-containing material film 151, etc. of the semiconductor substrate 100. Then, the silicon oxide film 154 is etched back such that the silicon oxide film 154 remains only on side surfaces of the patterned first silicon-containing material film 151, etc. over each transistor region to form offset spacers 109 as shown in FIG. 4B. After that, ions of N-type impurities are implanted into the N-channel transistor region to form source/drain extension regions 161, and ions of P-type impurities are implanted into the P-channel transistor region to form source/drain extension regions 162.

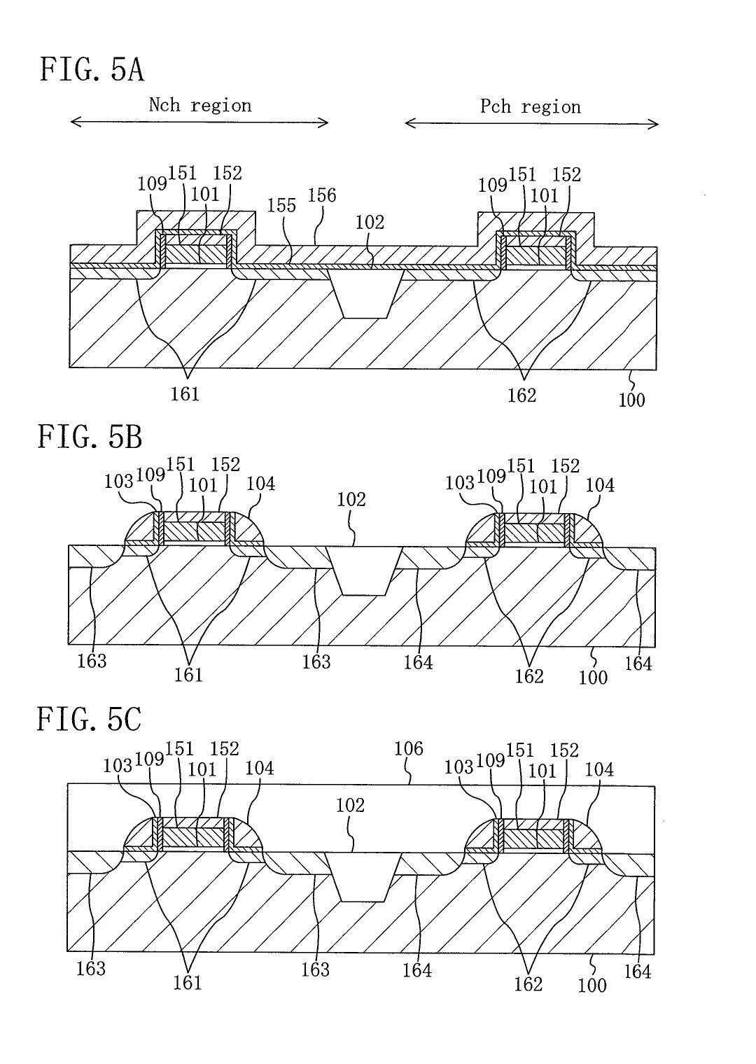

Next, as shown in FIG. 4C, over the entire surface including over the patterned first silicon-containing material film 151, etc. of the semiconductor substrate 100, a silicon oxide film 155 having, for example, a thickness of about 10 to 20 nm is formed. Then, as shown in FIG. 5A, on the silicon oxide film 155, a silicon nitride film 156 having, for example, a thickness of about 50 to 100 nm is formed. After that, as shown in 5B, the silicon nitride film 156 and the silicon oxide film 155 are etched back to form a sidewall oxide film 103 and a sidewall nitride film 104 on the offset spacers 109 formed on the side surfaces of the patterned first silicon-containing material film 151, etc. over each transistor region. Here, the thickness (i.e., the width in a gate length direction) of the sidewall nitride film 104 is set to about 50 to 90 nm so that the width of the semiconductor substrate (e.g., the silicon substrate) 100 exposed in an active region between gates is set to about 20 to 60 nm.

Next, ions of N-type impurities are implanted into the N-channel transistor region to form source/drain regions 163, and ions of P-type impurities are implanted into the P-channel transistor region to form source/drain regions 164.

Next, as shown in FIG. 5C, using, for example, a CVD apparatus or the like, an insulating film 106 which is, for example, a silicon oxide film having a thickness of about 300 to 500 nm is formed over the entire surface of the semiconductor substrate 100 to cover the patterned first silicon-containing material film 151, etc. Then, the surface of the insulating film 106 is planarized by, for example, chemical mechanical polishing.

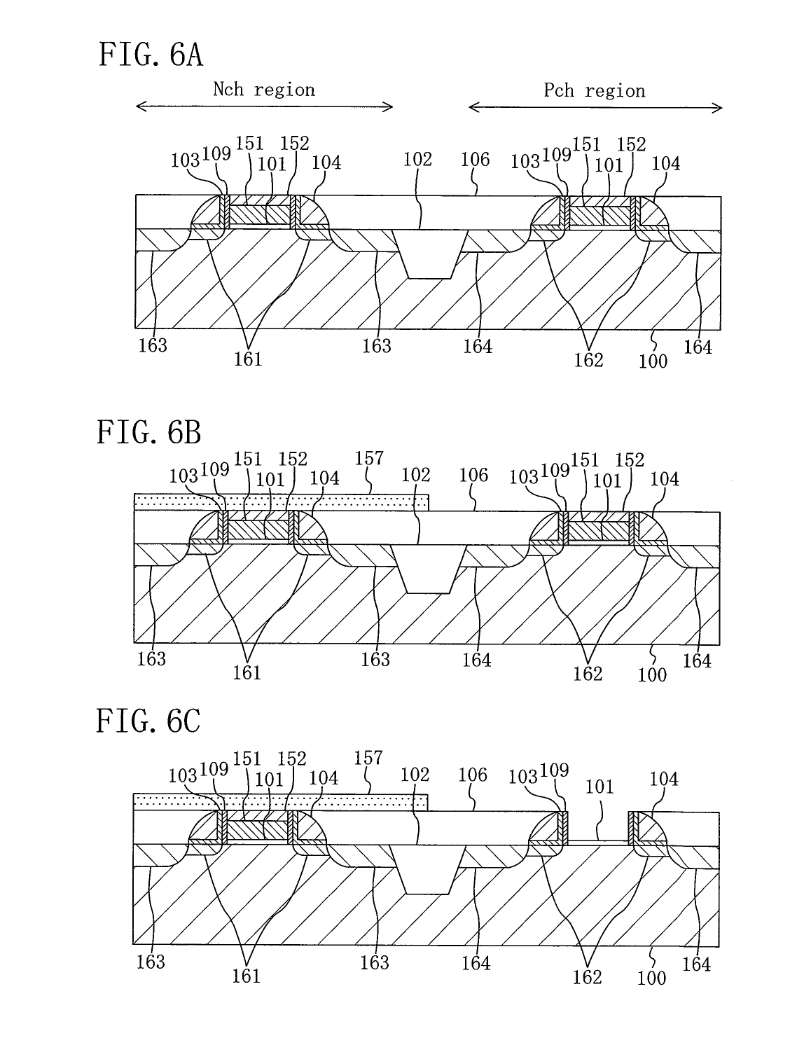

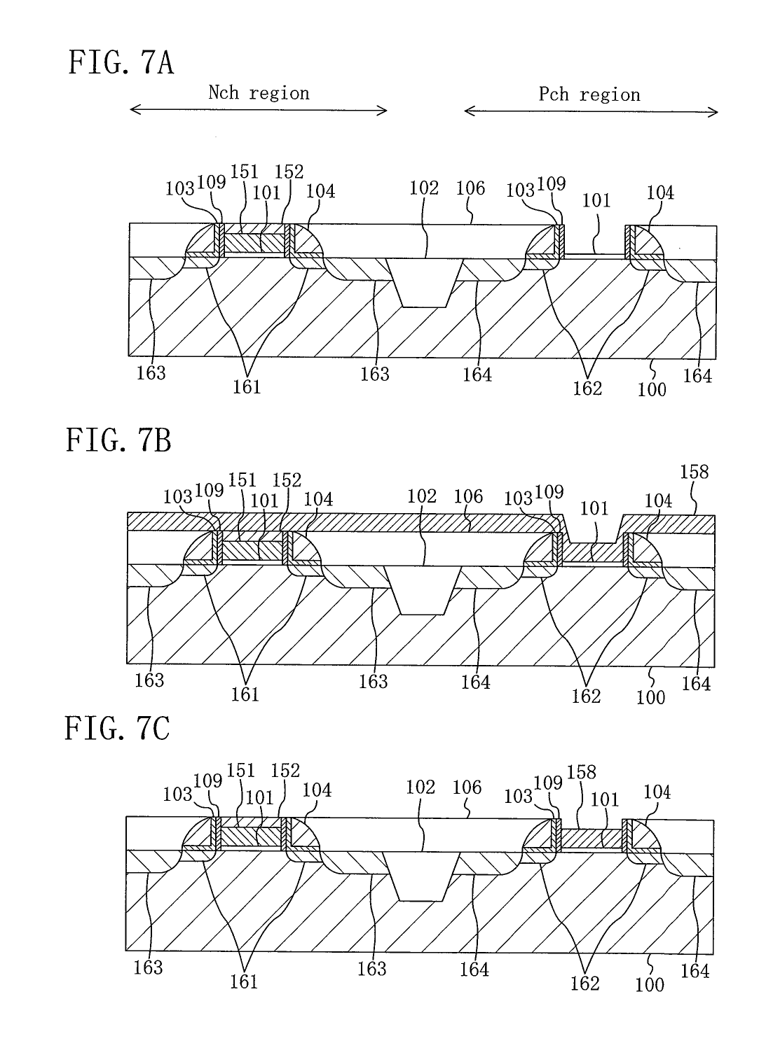

Next, as shown in FIG. 6A, the insulating film 106 is etched back so that the insulating film 106 has, for example, a thickness of about 50 to 100 nm. In the present embodiment, the insulating film 106 is etched back to expose an upper surface of the patterned hard mask film 152 in each transistor region. Next, as shown in FIG. 6B, a resist mask 157 covering regions other than the P-channel transistor region is formed. Then, as shown in FIG. 6C, using the resist mask 157, the patterned hard mask him 152 and the patterned first silicon-containing material film 151 over the P-channel transistor region are selectively removed by, for example, reactive ion etching. Here, in the present embodiment, the etching is performed such that the patterned gate insulating film 101 remains in the P-channel transistor region. Moreover, the etching of the hard mask film 152 is performed using a gas containing CF₄ under such conditions that the gas flow rate is 20 to 100 cc/min (standard condition), and the temperature is 20 to 50° C. Furthermore, the etching of the first silicon-containing material film 151 is performed by, for example, a gas mixture of SF₆ and CHF₃, a gas mixture of Cl₂, O₂, and HBr, and a gas mixture of Cl₂, HBr, and Ar which are used in this order under such conditions that the gas flow rate is 20 to 100 cc/min (standard condition), and the temperature is 20 to 50° C. After that, as shown in FIG. 7A, the resist mask 157 is removed by oxygen ashing.

Next, as shown in FIG. 7B, a second silicon-containing material film 158 which is lower in density than the first silicon-containing material (polysilicon) film 151 is deposited over the entire surface of the semiconductor substrate 100 including an opening (hereinafter referred to as an opening of the P-channel transistor region) formed by the process shown in FIG. 6C. The second silicon-containing material film 158 is made of, for example, porous silicon or organic silicon, and has a thickness of about 30 to 100 nm.

For example, an organic solvent containing polysilane obtained by polymerizing cyclopentasilane by ultraviolet light is applied on the semiconductor substrate 100 by spin coating or an inkjet method at a temperature of about 500 to 550° C. In this way, a second silicon-containing material film 158 made of porous silicon can be deposited.

Alternatively, for depositing a second silicon-containing material film 158 made of organic silicon, an organic-based silicon-containing resist material (e.g., cyclopentasilane), a silicon-containing material for application and polishing, a metal containing mixture, or the like may be used. In the case of using cyclopentasilane, 1 mg of 1-phospho cyclopentane which is silane compound modified by phosphorus and 1 g of octasilacubane are dissolved in a mixed solvent of tetrahydronaphthalene and 10 g of toluene to adjust an application solvent. The application solvent is applied on the substrate by spin coating in an argon atmosphere, and then is dried at a temperature of 150° C. After that, the application solvent is subjected to a thermal decomposition treatment in an argon atmosphere containing 3 vol % of hydrogen at a temperature of 450° C. In this way, the second silicon-containing material film 158 made of organic silicon can be deposited.

Since cyclopentasilane has a structure containing no carbon, the organic silicon film made of cyclopentasilane contains only residual carbon contained in the solvent, and thus using the organic silicon film provides the advantage that a gate electrode having relatively small resistance can be formed. Note that, as a material capable of providing an effect similar to that of cyclopentasilane, a silane compound having a straight chain structure such as SiH₃—(SiH₂)n-SiH₃ or a silane compound having a cyclic structure other than cyclopentasilane may be used, or the liquid silicon material described, for example, in Non-Patent Document 1 may be used.

Note that when the second silicon-containing material film 158 made of organic silicon is silicided, the resulting silicide layer contains an organic substance contained in the organic silicon.

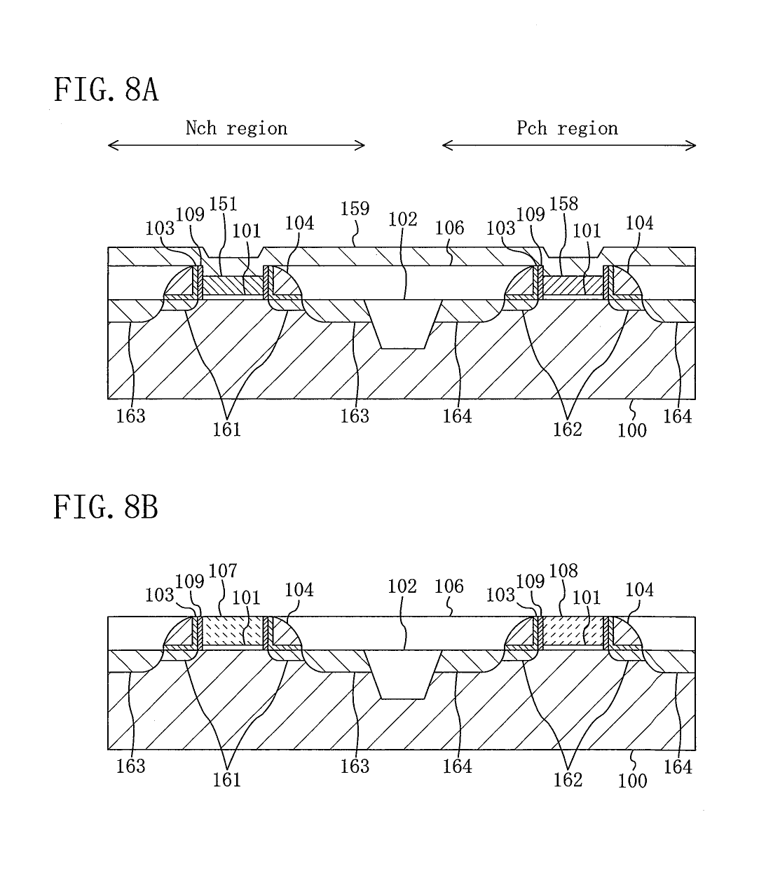

Next, as shown in FIG. 7C, the second silicon-containing material film 158 deposited outside the opening of the P-channel transistor region is removed by, for example, chemical mechanical polishing. Next, as shown in FIG. 8A, the patterned hard mask film 152 over the N-channel transistor region is removed. After that, over the entire surface of the semiconductor substrate 100, a metal film 159 such as a nickel film having a thickness of about 80 to 120 nm is formed by, for example, sputtering such that the metal film 159 is in contact with the patterned first silicon-containing material film 151 over the N-channel transistor region, and with the second silicon-containing material film 158 remaining in the opening of the P-channel transistor region.

Next, the semiconductor substrate 100 is subjected to a thermal treatment for silicidation so that the first silicon-containing material film 151 and the second silicon-containing material film 158 react with the metal film 159, thereby being fully silicided. After that, part of the metal film 159 which remains unreacted is selectively removed. As the thermal treatment for silicidation, for example, a process in which a Rapid Thermal Process (RTP) at a thermal treatment temperature of about 400 to 600° C. is performed in two steps is used. In this way, as shown in FIG. 8B, a first FUSI electrode 107 and a second FUSI electrode 108 are formed. After that, surfaces of the first FUSI electrode 107 and the second FUSI electrode 108 are planarized by, for example, chemical mechanical polishing.

As described above, according to Embodiment 1, a common silicon-containing material, for example, polysilicon is not used to form a silicide constituting the gate electrodes of the N-channel transistor and the P-channel transistor, but for example, ordinary polysilicon (first silicon-containing material film 151) is used for siliciding the FUSI electrode 107 of the N-channel transistor, while a silicon-containing material (second silicon-containing material film 158) which is lower in density than the FUSI electrode 107 of the N-channel transistor, such as porous silicon or organic silicon, is used for siliciding the FUSI electrode 108 of the P-channel transistor. Therefore, tensile stress caused by volume expansion of the first silicon-containing material film 151 during silicidation can be sufficiently applied to the N-channel transistor, which allows the performance of the N-channel transistor to be improved. At the same time, application of tensile stress to the P-channel transistor caused by volume expansion of the second silicon-containing material film 158 during the silicidation can be suppressed, which allows the performance of the P-channel transistor to be improved. That is, even in the case of miniaturizing the device, controlling stress inside the gate electrodes allows the performance of the P-channel transistor and the N-channel transistor to be improved in a FUSI gate process or other processes.

Moreover, according to Embodiment 1, stress can be controlled without using a thick liner nitride film, and thus it is possible to prevent the occurrence of a crystal defect, etc. caused by a crack in the liner nitride film, which is a critical problem for a device, and to easily form contacts in the periphery of the gate electrodes. Note that it is possible to simultaneously use a liner nitride film whose thickness or stress is sufficiently small or low so that no cracks occur.

Furthermore, according to Embodiment 1, since FUSI electrodes are used as the gate electrodes of the transistors, depletion of the gate electrodes can be suppressed. Therefore, an ON current of each transistor can be increased, which allows the operating speed of the integrated circuit to be improved.

Note that, in Embodiment 1, the same gate insulating film 101 is formed over the transistor regions before depositing the first silicon-containing material film 151, but instead of the same gate insulating film, different gate insulating films over the transistor regions may be formed according to the characteristics of the transistor regions.

Moreover, in Embodiment 1, the first silicon-containing material film 151 for forming the FUSI electrode 107 of the N-channel transistor is first formed, and then the second silicon-containing material film 158 for forming the FUSI electrode 108 of the P-channel transistor is formed, but alternatively, these silicon-containing material films may be formed in reverse order. That is, in the method for fabricating the semiconductor device according to Embodiment 1 shown in FIGS. 2A-2C, FIGS. 3A-3C, FIGS. 4A-4C, FIGS. 5A-5C, FIGS. 6A-6C, FIGS. 7A-7C, and FIGS. 8A, and 8B, even when the N-channel transistor region and the P-channel transistor region are interchanged, and a material constituting the first silicon-containing material film 151 and a material constituting the second silicon-containing material film 158 are interchanged, it is possible to achieve an effect similar to that of the present embodiment.

Moreover, in Embodiment 1, in order to silicide the first silicon-containing material film 151 and the second silicon-containing material film 158, the same metal film 159 is used, but instead of the same metal film, different metal films may be used to silicide the silicon-containing material films.

### First Variation of Embodiment 1

In Embodiment 1, the metal film 159 is deposited (FIG. 8A) at which time the insulating film 106 covering the source/drain regions 163 and 164 is not removed, so that surface portions of the source/drain regions 163 and 164 are not silicided. By contrast, in the present variation, the FUSI electrodes 107 and 108 are formed (FIG. 8B) after which time the removal of the insulating film 106, the deposition of a metal film for forming a silicide, a thermal treatment for silicidation, and the removal of unreacted metal are sequentially performed to form a silicide layer in the surface portions of the source/drain regions 163 and 164.

According to the present variation, it is possible to form a thin silicide layer on surfaces of the source/drain regions, which is an object of the FUSI gate process of fully siliciding the gate electrodes. Therefore, it is possible to form a shallower junction, which allows a so-called short channel effect to be suppressed.

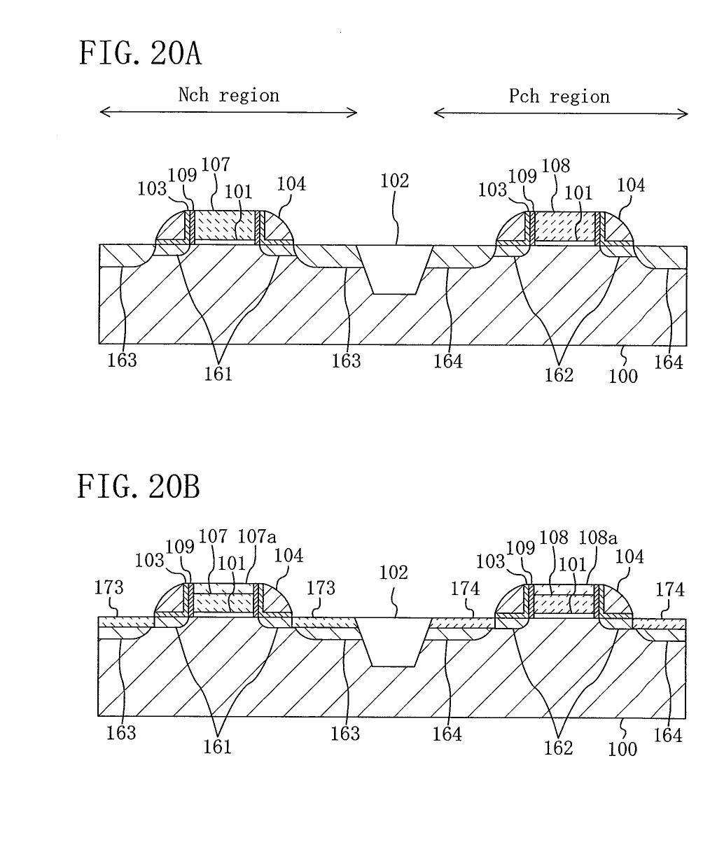

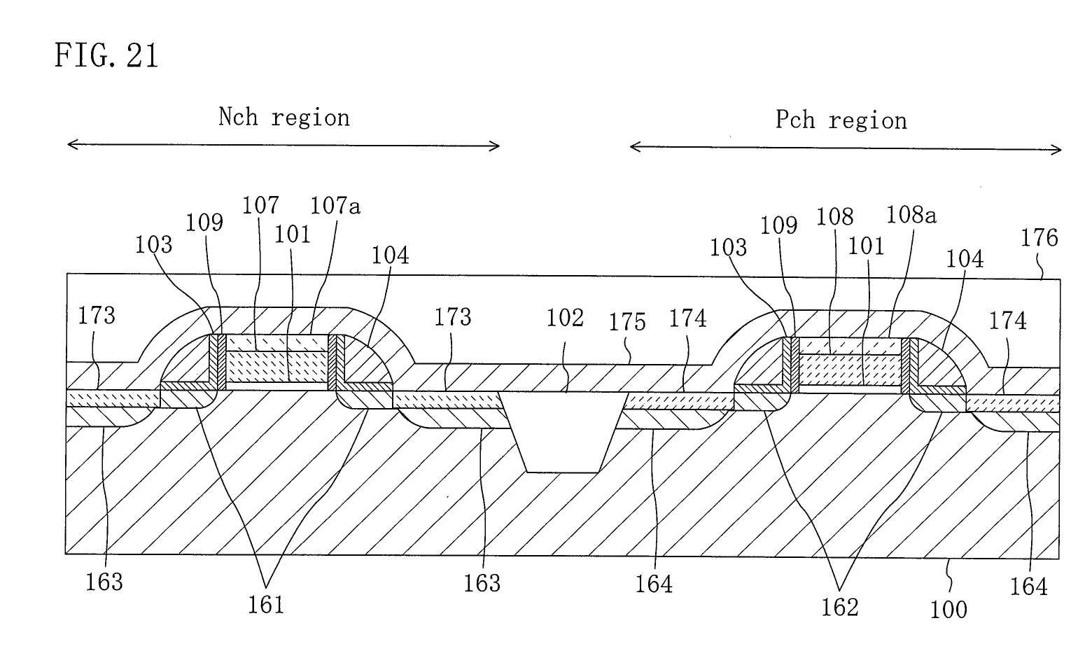

FIGS. 20A and 20B, and FIG. 21 are cross-sectional views showing processes in a method for fabricating a semiconductor device according to the present variation. Note that, in FIGS. 20A and 20B, and FIG. 21, the same reference characters as those shown in Embodiment 1 of FIGS. 2A-2C, FIGS. 3A-3C, FIGS. 4A-4C, FIGS. 5A-5C, FIGS. 6A-6C, FIGS. 7A-7C, and FIGS. 8A and 8B are used to represent equivalent elements, and the same explanation thereof will be omitted.

After the process of forming the FUSI electrodes 107 and 108 of Embodiment 1 shown in FIG. 8B is completed, the insulating film 106 covering the surface of the semiconductor substrate 100 is first removed as shown in FIG. 20A. After that, a metal film (not shown) is formed over the surface including over the surfaces of the source/drain regions 163 and 164 of the semiconductor substrate 100, and then is subjected to a thermal treatment for silicidation. This causes the reaction of the metal film and a silicon material in the surface portions of the source/drain regions to form a silicide layer 173 in the surface portions of the source/drain regions 163 and a silicide layer 174 in the surface portions of the source/drain regions 164 as shown in FIG. 20B. Here, in surface portions of the FUSI electrodes 107 and 108, re-silicide layers 107a and 108a are formed. After that, part of the metal film which remains unreacted is selectively removed.

Next, as shown in FIG. 21, over the semiconductor substrate 100 including over the FUSI electrodes 107 and 108, a liner nitride film 175 whose thickness or stress is sufficiently small or low so that no cracks occur is formed, and then an interlayer insulating film 176 is formed on the liner nitride film 175.

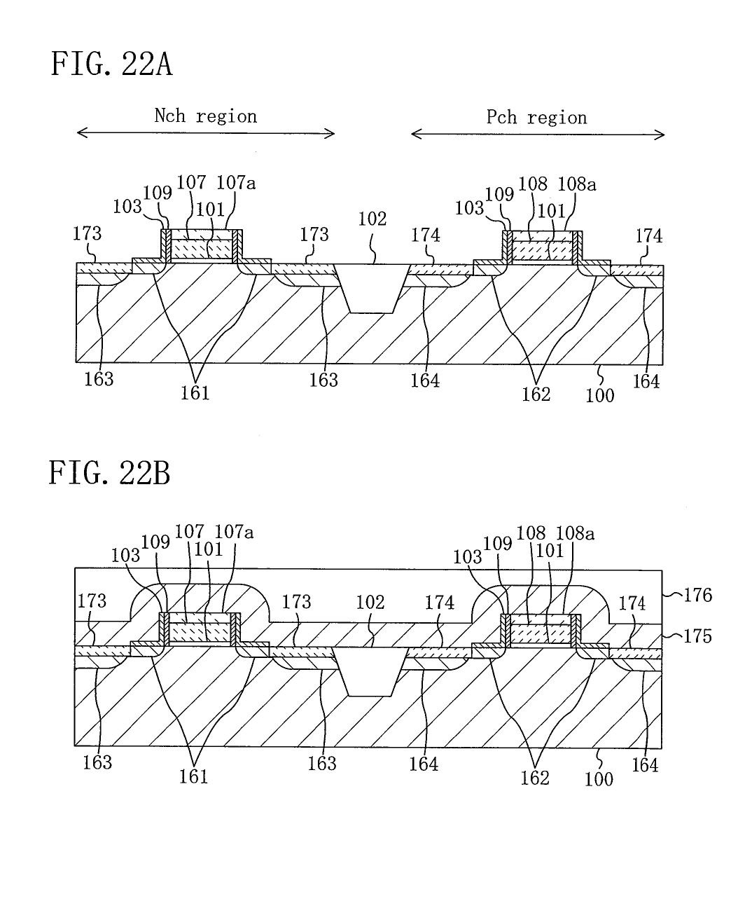

Note that, after the insulating film 106 is removed in the process shown in FIG. 20A of the present variation, the sidewall nitride film 104 may be removed, and then, as in the case of the present variation, the process of forming the silicide layers 173 and 174 shown in FIG. 22A, and the process of forming the liner nitride film 175 and the interlayer insulating film 176 shown in FIG. 22B may be performed. In this case, it is possible to obtain a disposable sidewall structure.

### Second Variation of Embodiment 1

In Embodiment 1, the metal film 159 is deposited (FIG. 8A) at which time the insulating film 106 covering the source/drain regions 163 and 164 is not removed. However, in the present variation, before depositing the metal film 159, the insulating film 106 is removed to form silicided electrodes using the metal film 159, and at the same time, to silicide the surface portions of the source/drain regions 163 and 164. In forming the silicided electrodes, gate electrodes may be fully silicided to form FUSI electrodes as in the case of Embodiment 1. However, an effect similar to that of Embodiment 1 can be achieved by siliciding only surface portion or surface portions of one or both of the gate electrodes of the N-channel transistor and the P-channel transistor. In other words, it may not be required to fully silicide the gate electrodes to achieve the effect similar to that of Embodiment 1. This configuration can be achieved by adjusting, for example, the thickness of the first silicon-containing material film 151 and the second silicon-containing material film 158, the material and the thickness of the metal film 159, and conditions for the thermal treatment for silicidation.

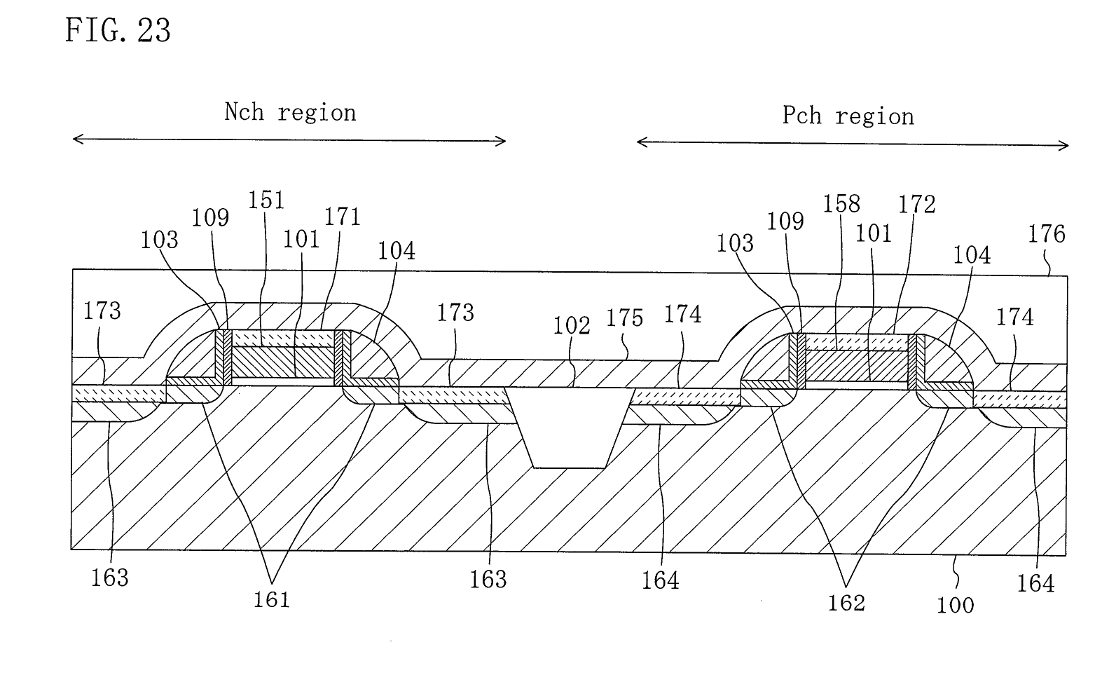

FIG. 23 is a cross-sectional view showing a structure of a semiconductor device according to the present variation. Note that, in FIG. 23, the same reference characters as those shown in Embodiment 1 of FIG. 1 are used to represent equivalent elements, and the same explanation thereof will be omitted.

The present variation is different from Embodiment 1 of FIG. 1 in the following points. For one thing, as shown in FIG. 23, instead of the first FUSI electrode 107 of the N-channel transistor region, a gate electrode including the first silicon-containing material film (silicon electrode part) 151 and a first silicide layer (silicided electrode part) 171 obtained by siliciding the first silicon-containing material film 151 is provided. Moreover, instead of the second FUSI electrode 108 of the P-channel transistor region, a gate electrode including the second silicon-containing material film (silicon electrode part) 158 and a second silicide layer (silicided electrode part) 172 obtained by siliciding the second silicon-containing material film 158 is provided.

Note that, as in the case of the above-described first variation, in the present variation, a silicide layer 173 is provided in the surface portions of the source/drain regions 163, and a silicide layer 174 is provided in the surface portions of the source/drain regions 164. Moreover, over the semiconductor substrate 100 including over the gate electrodes of the transistor regions, a liner nitride film 175 whose thickness or stress is sufficiently small or low so that no cracks occur is provided. An interlayer insulating film 176 is provided on the liner nitride film 175.

In the case of using no FUSI electrodes as in the case of the present variation, even if the liner nitride film 175 whose thickness or stress is sufficiently small or low so that no cracks occur is simultaneously used, that is, even if tensile stress by the liner nitride film 175 is caused in addition to tensile stress in the second silicon-containing material film 158 constituting the gate electrode, the tensile stress may not become excessive because the Young's modulus of the second silicon-containing material film 158 (e.g., organic silicon film) constituting the gate electrode of the P-channel transistor region is small.

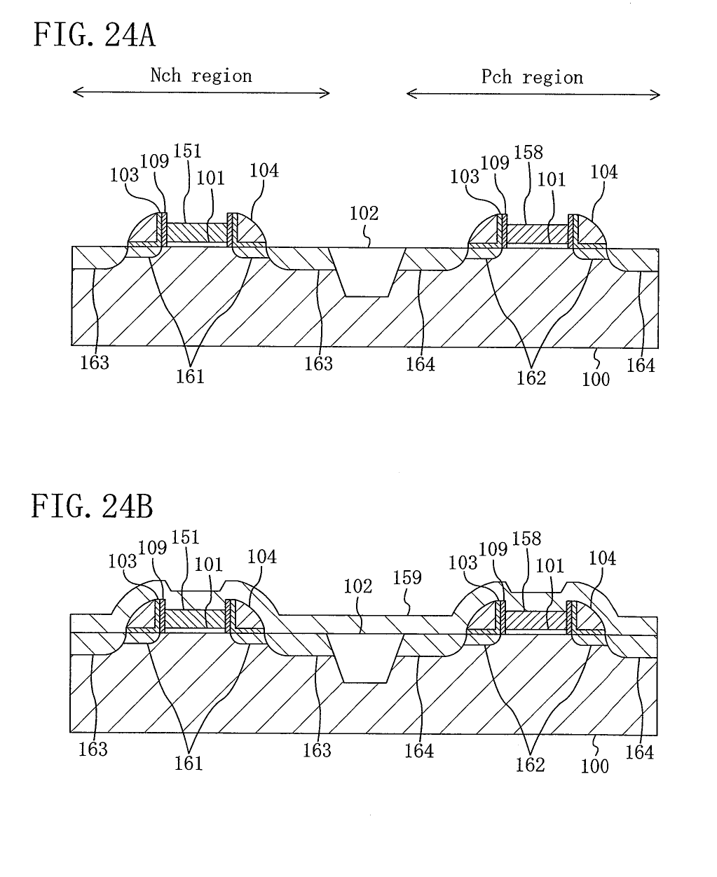

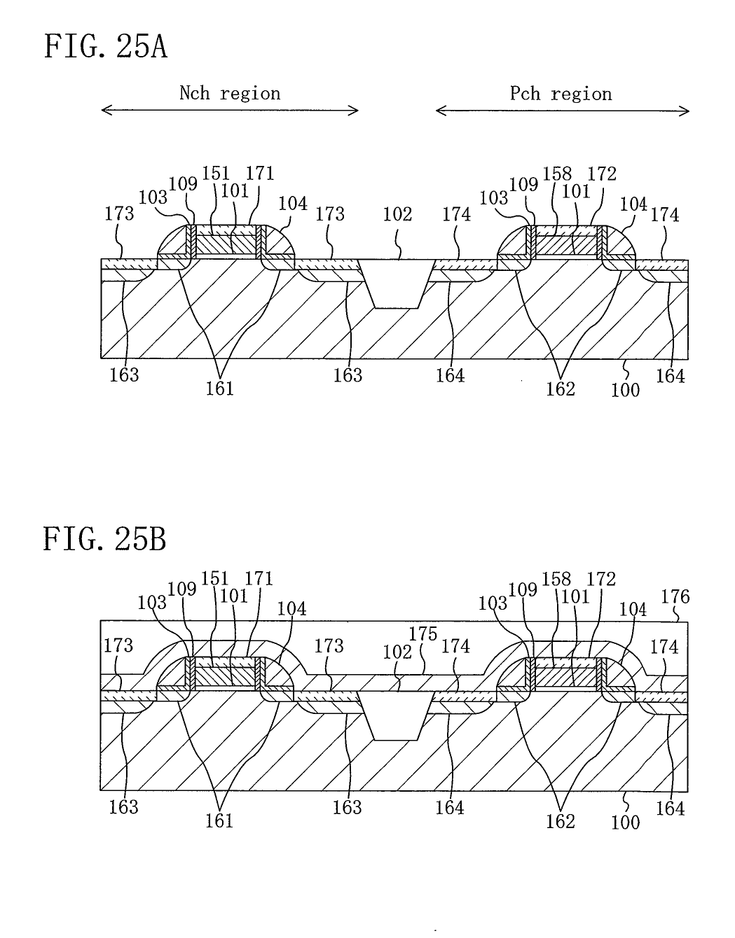

FIGS. 24A and 24B, and FIGS. 25A and 25B are cross-sectional views showing processes in a method for fabricating a semiconductor device according to the present variation. Note that, in FIGS. 24A and 24B, and FIGS. 25A and 25B, the same reference characters as those shown in Embodiment 1 of FIGS. 2A-2C, FIGS. 3A-3C, FIGS. 4A-4C, FIGS. 5A-5C, FIGS. 6A-6C, FIGS. 7A-7C, and FIGS. 8A and 8B are used to represent equivalent elements, and the same explanation thereof will be omitted.

After the process of polishing the second silicon-containing material film 158 of Embodiment 1 shown in FIG. 7C is completed, the hard mask film 152 of the N-channel transistor region is first removed, and the insulating film 106 covering the surface of the semiconductor substrate 100 is removed as shown in FIG. 24A.

Next, as shown in FIG. 24B, over the entire surface of the semiconductor substrate 100, a metal film 159 such as a nickel film having a thickness of about 80 to 120 nm is formed by, for example, sputtering such that the metal film 159 is in contact with the first silicon-containing material film 151 and the source/drain regions 163 over the N-channel transistor region, and with the second silicon-containing material film 158 and the source/drain regions 164 over the P-channel transistor region.

Next, a thermal treatment for silicidation is performed so that surface portions of the first silicon-containing material film 151 and the second silicon-containing material film 158 react with the metal film 159, thereby being silicided. After that, part of the metal film 159 which remains unreacted is selectively removed. As the thermal treatment for silicidation, for example, a process in which a Rapid Thermal Process (RTP) at a thermal treatment temperature of about 400 to 600° C. is performed in two steps is used. In this way, as shown in FIG. 25A, in the N-channel transistor region, a gate electrode including the first silicon-containing material film (silicon electrode part) 151 and a first silicide layer (silicided electrode part) 171 obtained by siliciding the first silicon-containing material film 151 is formed. In the P-channel transistor region, a gate electrode including the second silicon-containing material film (silicon electrode part) 158 and a second silicide layer (silicided electrode part) 172 obtained by siliciding the second silicon-containing material film 158 is formed. Moreover, in the thermal treatment for silicidation, the metal film 159 reacts with a silicon material of the surface portions of the source/drain regions, thereby forming a silicide layer 173 in the surface portions of the source/drain regions 163, and a silicide layer 174 in the surface portions of the source/drain regions 164.

Next, as shown in FIG. 25B, over the semiconductor substrate 100 including the gate electrodes of the transistor regions, a liner nitride film 175 whose thickness or stress is sufficiently small or low so that no cracks occur is formed, and then an interlayer insulating film 176 is formed on the liner nitride film 175.

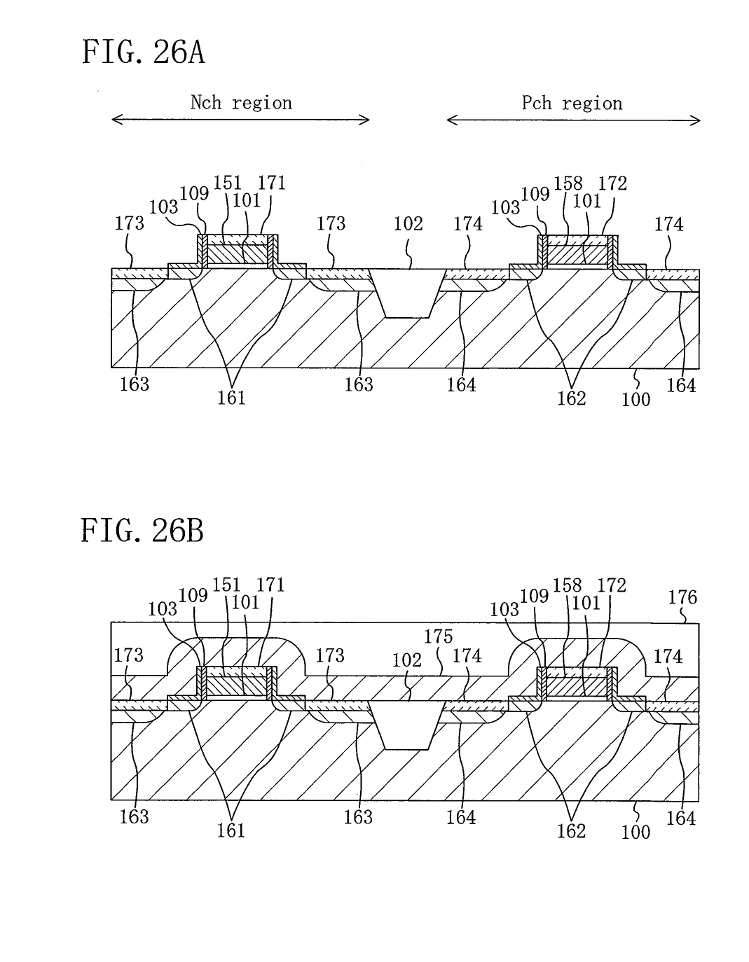

Note that, after the removal of the insulating film 106 in the process shown in FIG. 24A of the present variation, the sidewall nitride film 104 may be removed, and then, as in the case of the present variation, the process of forming the silicide layers 171-174 shown in FIG. 26A and the process of forming the liner nitride film 175 and the interlayer insulating film 176 shown in FIG. 26B may be performed.

### Embodiment 2

A semiconductor device according to Embodiment 2 of the present disclosure and a method for fabricating the same will be described below with reference to the drawings.

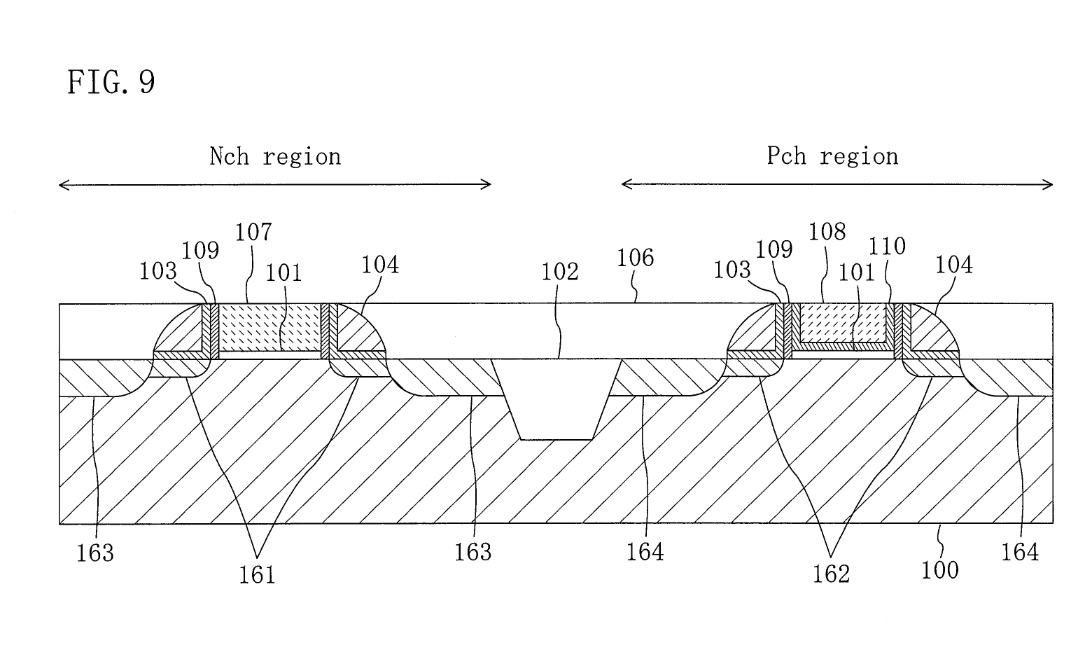

FIG. 9 is a cross-sectional view showing a structure of the semiconductor device according to Embodiment 2 of the present disclosure. Note that, in FIG. 9, the same reference characters as those of the semiconductor device according to Embodiment 1 of FIG. 1 are used to represent equivalent elements, and the same explanation thereof will be omitted.

As shown in FIG. 9, the semiconductor device according to Embodiment 2 is different from the semiconductor device according to Embodiment 1 of FIG. 1 in that a metal layer 110 made of, for example, a TiN film having a thickness of about 5 to 15 nm is provided between a second FUSI electrode 108 of a P-channel transistor and a gate insulating film 101 and between the second FUSI electrode 108 and offset spacers 109. That is, in Embodiment 2, the gate electrode of the P-channel transistor has a multilayer structure including the second FUSI electrode 108 and the metal layer 110.

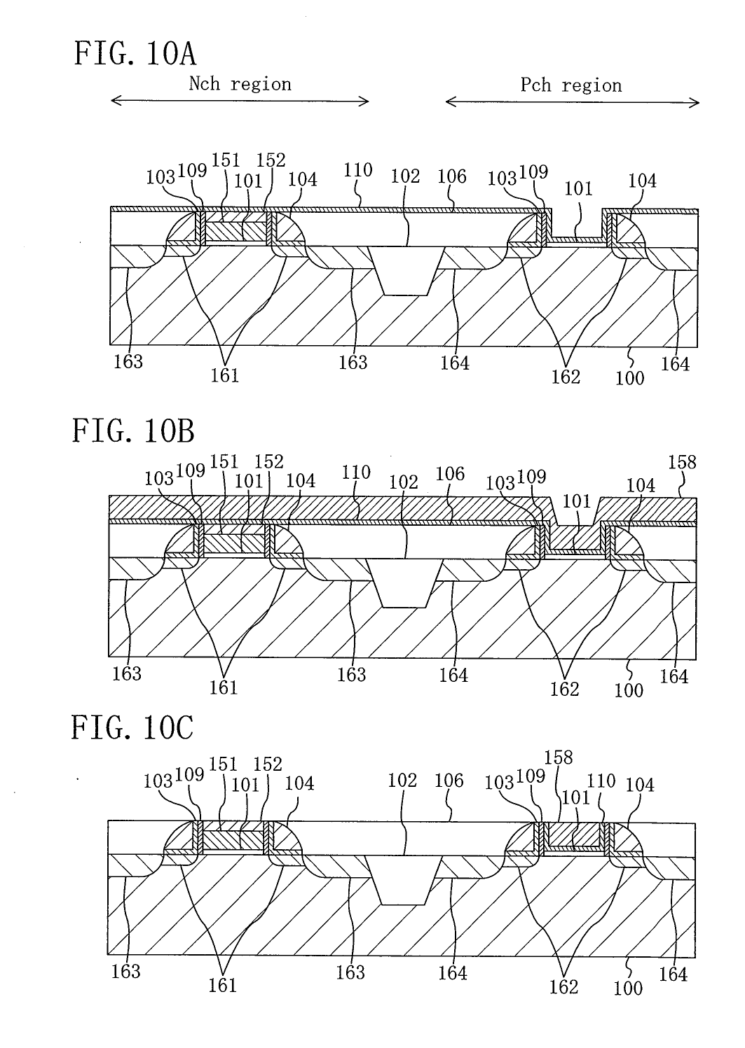

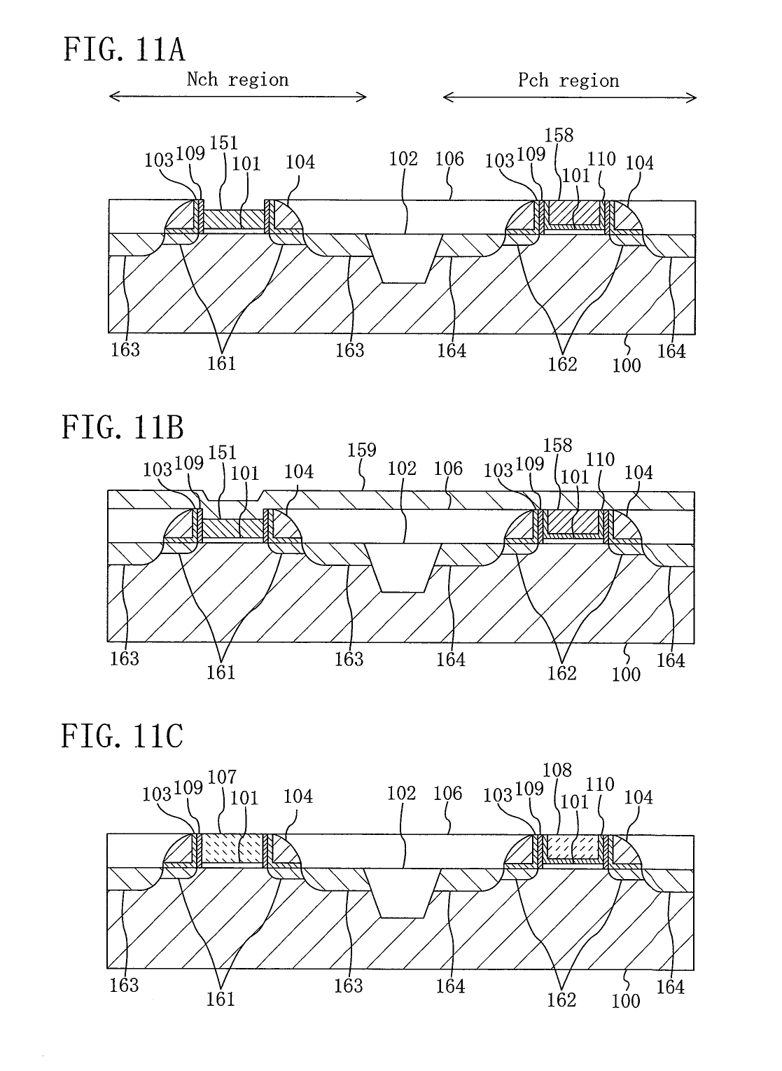

FIGS. 10A-10C, and FIGS. 11A-11C are cross-sectional views showing processes in the method for fabricating the semiconductor device according to Embodiment 2. Note that, in FIGS. 10A-10B, and FIGS. 11A-11C, the same reference characters as those shown in Embodiment 1 of FIGS. 2A-2C, FIGS. 3A-3C, FIGS. 4A-4C, FIGS. 5A-5C, FIGS. 6A-6C, FIGS. 7A-7C, and FIGS. 8A and 8B are used to represent equivalent elements, and the same explanation thereof will be omitted.

In the method for fabricating the semiconductor device according to Embodiment 2, first, the processes shown in FIGS. 2A-2C, FIGS. 3A-3C, FIGS. 4A-4C, FIGS. 5A-5C, FIGS. 6A-6C, and FIG. 7A in the method for fabricating the semiconductor device according to Embodiment 1 are sequentially performed.

Next, as shown in FIG. 10A, over the entire surface including the opening of the P-channel transistor region of the semiconductor substrate 100, a metal layer 110 which is, for example, a TiN film having a thickness of about 5 to 15 nm is formed.

Next, as shown in FIG. 10B, on the entire surface of the metal layer 110, a second silicon-containing material film 158 which is lower in density than the first silicon-containing material (polysilicon) film 151 is deposited. The second silicon-containing material film 158 is made of, for example, porous silicon or organic silicon, and has a thickness of about 30 to 100 nm. Details of a method for depositing the second silicon-containing material film 158 are similar to those of Embodiment 1 (the process shown in FIG. 7B).

Next, as shown in FIG. 10C, the second silicon-containing material film 158 and the metal layer 110 deposited outside the opening of the P-channel transistor region are removed by, for example, chemical mechanical polishing. Next, as shown in FIG. 11A, the patterned hard mask film 152 over the N-channel transistor region is removed. After that, as shown in FIG. 11B, over the entire surface of the semiconductor substrate 100, a metal film 159 such as a nickel film having a thickness of about 80 to 120 nm is formed by, for example, sputtering such that the metal film 159 is in contact with the patterned first silicon-containing material film 151 over the N-channel transistor region, and with the second silicon-containing material film 158 remaining in the opening of the P-channel transistor region.

Next, the semiconductor substrate 100 is subjected to a thermal treatment for silicidation so that the first silicon-containing material film 151 and the second silicon-containing material film 158 react with the metal film 159, thereby being fully silicided. After that, part of the metal film 159 which remains unreacted is selectively removed. As the thermal treatment for silicidation, for example, a process in which a RTP at a thermal treatment temperature of about 400 to 600° C. is performed in two steps is used. In this way, as shown in FIG. 11C, a first FUSI electrode 107 and a second FUSI electrode 108 are formed. After that, surfaces of the first FUSI electrode 107 and the second FUSI electrode 108 are planarized by, for example, chemical mechanical polishing.

According to Embodiment 2 described above, the gate electrode of the P-channel transistor includes the metal layer 110 formed between the second FUSI electrode 108 and the gate insulating film 101, so that it is possible to achieve, in addition to an effect similar to that of Embodiment 1, the effect that the threshold voltage (Vt) of the P-channel transistor can be controlled easily.

Note that, in Embodiment 2, TiN is used as a material for the metal layer 110, but instead of TiN, other metal materials having, for example, a work function (W) of 4.7 eV or larger may be used. Specifically, the following film may be used: a single-layer film which is a metal film made of at least one metal (or which is an alloy film when two or more metals are) selected from a metal group consisting of Ni, Pd, Pt, Co, Rh, Ru, Cu, Ag, Au, Ti, Zr, Hf, V, Nb, Ta, Cr, Mo, and W; a single-layer film made of a silicide, a carbide, or a nitride of at least one metal selected from the metal group above; or a multilayer film including these metal films (including the case where the metals are silicided, carbonized, or nitrided).

Moreover, in Embodiment 2, the gate electrode of the P-channel transistor includes the metal layer 110 formed between the second FUSI electrode 108 and the gate insulating film 101, but alternatively or additionally, the gate electrode of the N-channel transistor may have a metal layer formed between the first FUSI electrode 107 and the gate insulating film 101.

### First Variation of Embodiment 2

In Embodiment 2, the metal film 159 is deposited (FIG. 11B) at which time the insulating film 106 covering the source/drain regions 163 and 164 is not removed, so that surface portions of the source/drain regions 163 and 164 are not silicided. By contrast, in the present variation, the FUSI electrodes 107 and 108 are formed (FIG. 11C) after which time the removal of the insulating film 106, the deposition of a metal film for forming a silicide, a thermal treatment for silicidation, and the removal of unreacted metal are sequentially performed to form a silicide layer in the surface portions of the source/drain regions 163 and 164.

According to the present variation, it is possible to form a thin silicide layer on surfaces of the source/drain regions, which is an object of the FUSI gate process of fully siliciding the gate electrodes. Therefore, it is possible to form a shallower junction, which allows a so-called short channel effect to be suppressed.

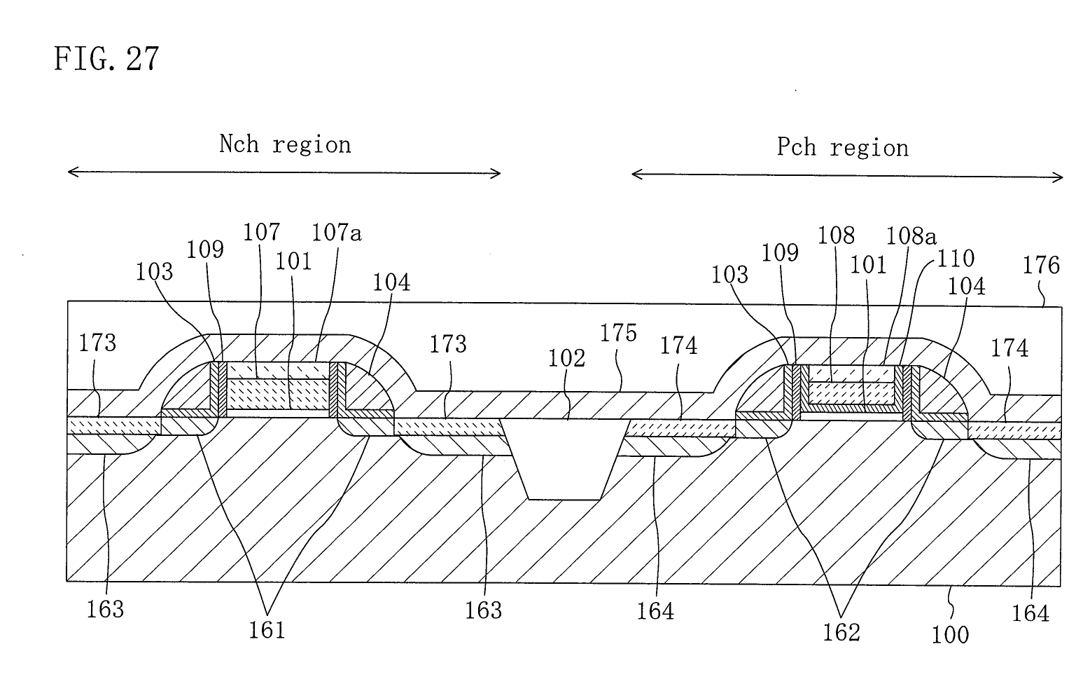

FIG. 27 is a cross-sectional view showing a structure of a semiconductor device according to the present variation. Note that, in FIG. 27, the same reference characters as those shown in Embodiment 2 of FIG. 9 are used to represent equivalent elements, and the same explanation thereof will be omitted.

The present variation is different from Embodiment 2 of FIG. 9 in the following points. For one thing, as shown in FIG. 27, a silicide layer 173 is provided in the surface portions of the source/drain regions 163, and a silicide layer 174 is provided in the surface portions of the source/drain regions 164. Note that, in the surface portions of the FUSI electrodes 107 and 108, re-silicide layers 107a and 108a are provided. Moreover, over the semiconductor substrate 100 including over the gate electrodes of the transistor regions, a liner nitride film 175 whose thickness or stress is sufficiently small or low so that no cracks occur is provided, and an interlayer insulating film 176 is provided on the liner nitride film 175.

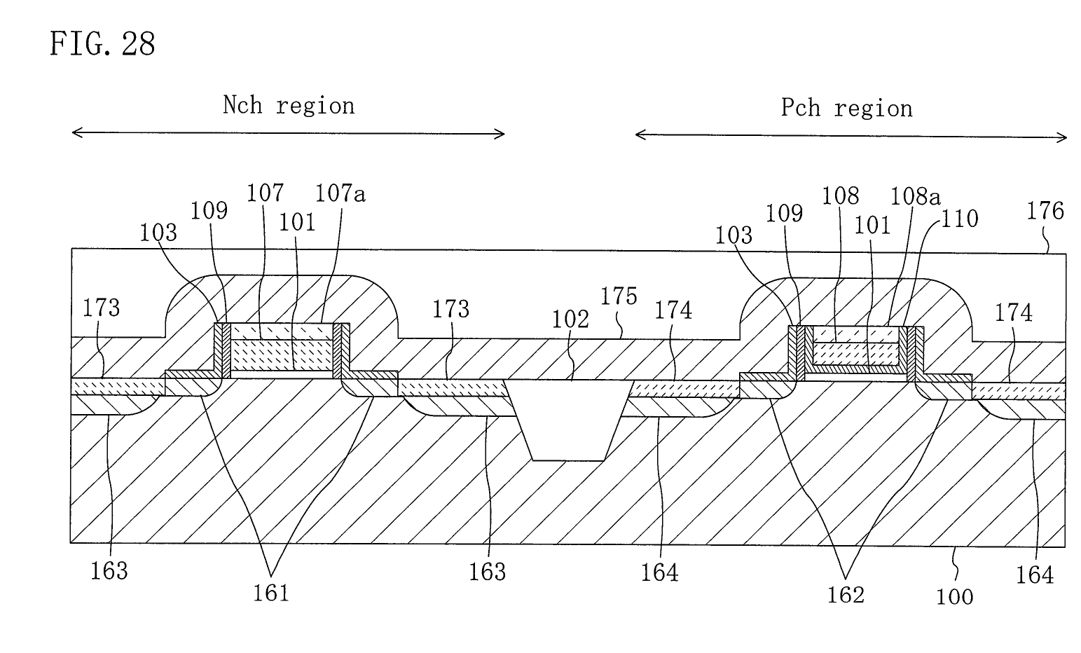

Note that the method for fabricating the semiconductor device according to the present variation of FIG. 27 is basically the same as that of the first variation of Embodiment 1 of FIGS. 20A and 20B, and FIG. 21. Moreover, in fabricating the semiconductor device according to the present variation, after the insulating film 106 is removed, the sidewall nitride film 104 may be removed, and then the process of forming the silicide layers 173 and 174 and the process of forming the liner nitride film 175 and the interlayer insulating film 176 may be performed. In this case, it is possible to obtain a disposable sidewall structure as shown in FIG. 28.

### Second Variation of Embodiment 2

In Embodiment 2, the metal film 159 is deposited (FIG. 11B) at which time the insulating film 106 covering the source/drain regions 163 and 164 is not removed. However, in the present variation, before depositing the metal film 159, the insulating film 106 is removed to form silicided electrodes using the metal film 159, and at the same time, to silicide the surface portions of the source/drain regions 163 and 164. In forming the silicided electrodes, gate electrodes may be fully silicided to form FUSI electrodes as in the case of Embodiment 2. However, an effect similar to that of Embodiment 2 can be achieved by siliciding only surface portion or surface portions of one or both of the gate electrodes of the N-channel transistor and the P-channel transistor. In other words, it may not be required to fully silicide the gate electrodes to achieve the effect similar to that of Embodiment 2. This configuration can be achieved by adjusting, for example, the thickness of the first silicon-containing material film 151 and the second silicon-containing material film 158, the material and the thickness of the metal film 159, and conditions for the thermal treatment for silicidation.

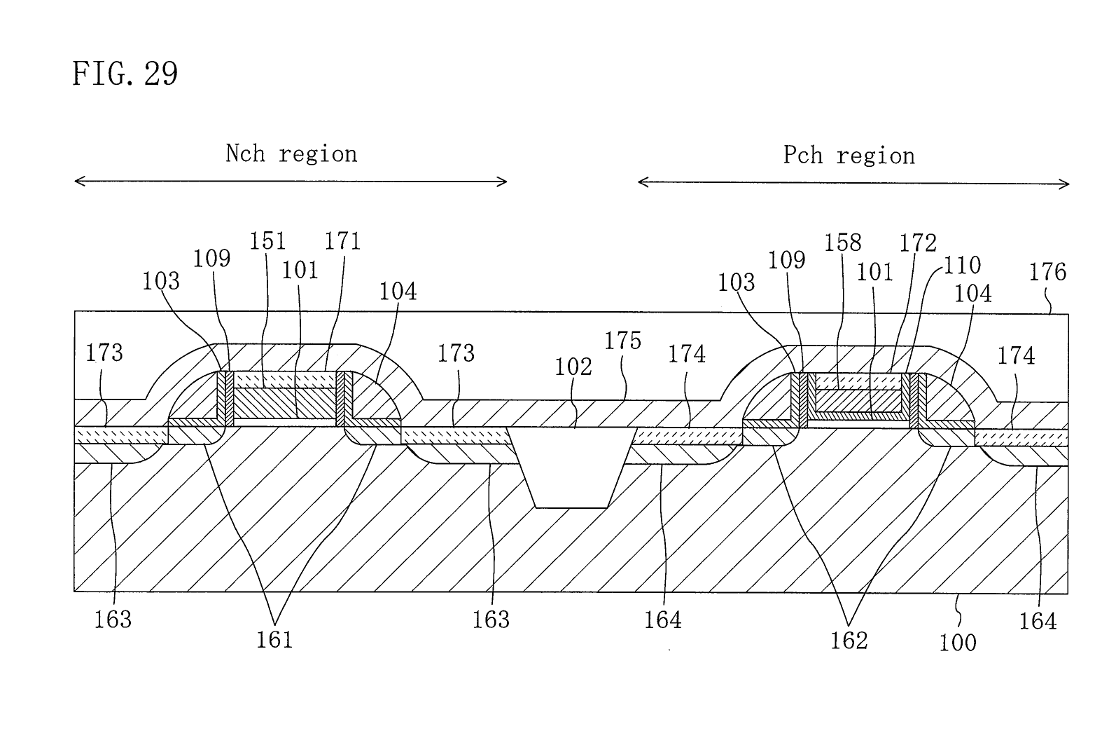

FIG. 29 is a cross-sectional view showing a structure of a semiconductor device according to the present variation. Note that, in FIG. 29, the same reference characters as those shown in Embodiment 2 of FIG. 9 are used to represent equivalent elements, and the same explanation thereof will be omitted.

The present variation is different from Embodiment 2 of FIG. 9 in the following points. For one thing, as shown in FIG. 29, instead of the first FUSI electrode 107 of the N-channel transistor region, a gate electrode including the first silicon-containing material film (silicon electrode part) 151 and a first silicide layer (silicided electrode part) 171 obtained by siliciding the first silicon-containing material film 151 is provided. Moreover, instead of the second FUSI electrode 108 of the P-channel transistor region, a gate electrode including the second silicon-containing material film (silicon electrode part) 158 and a second silicide layer (silicided electrode part) 172 obtained by siliciding the second silicon-containing material film 158 is provided. Note that the gate electrode of the P-channel transistor region further includes a metal layer 110 disposed between the second silicon-containing material film (silicon electrode part) 158 and the gate insulating film 101.

Note that, as in the case of the above-described first variation, in the present variation, a silicide layer 173 is provided in the surface portions of the source/drain regions 163, and a silicide layer 174 is provided in the surface portions of the source/drain regions 164. Moreover, over the semiconductor substrate 100 including over the gate electrodes of the transistor regions, a liner nitride film 175 whose thickness or stress is sufficiently small or low so that no cracks occur is provided. An interlayer insulating film 176 is provided on the liner nitride film 175.

In the case of using no FUSI electrodes as in the case of the present variation, even if the liner nitride film 175 whose thickness or stress is sufficiently small or low so that no cracks occur is simultaneously used, that is, even if tensile stress by the liner nitride film 175 is caused in addition to tensile stress in the second silicon-containing material film 158 constituting the gate electrode, the tensile stress may not become excessive because the Young's modulus of the second silicon-containing material film 158 (e.g., organic silicon film) constituting the gate electrode of the P-channel transistor region is small.

Moreover, even if no FUSI electrodes are used as in the case of the present variation, it is possible to suppress depletion of the gate electrode of the P-channel transistor because the gate electrode of the P-channel transistor further includes the metal layer 110 disposed between the second silicon-containing material film (silicon electrode part) 158 and the gate insulating film 101. Therefore, an ON current of the P-channel transistor can be increased, which enables the operating speed of the integrated circuit to be improved. Moreover, it is of course possible to obtain similar advantages for the gate electrode of the N-channel transistor by disposing a metal layer between the first silicon-containing material film (silicon electrode part) 151 and the gate insulating film 101.

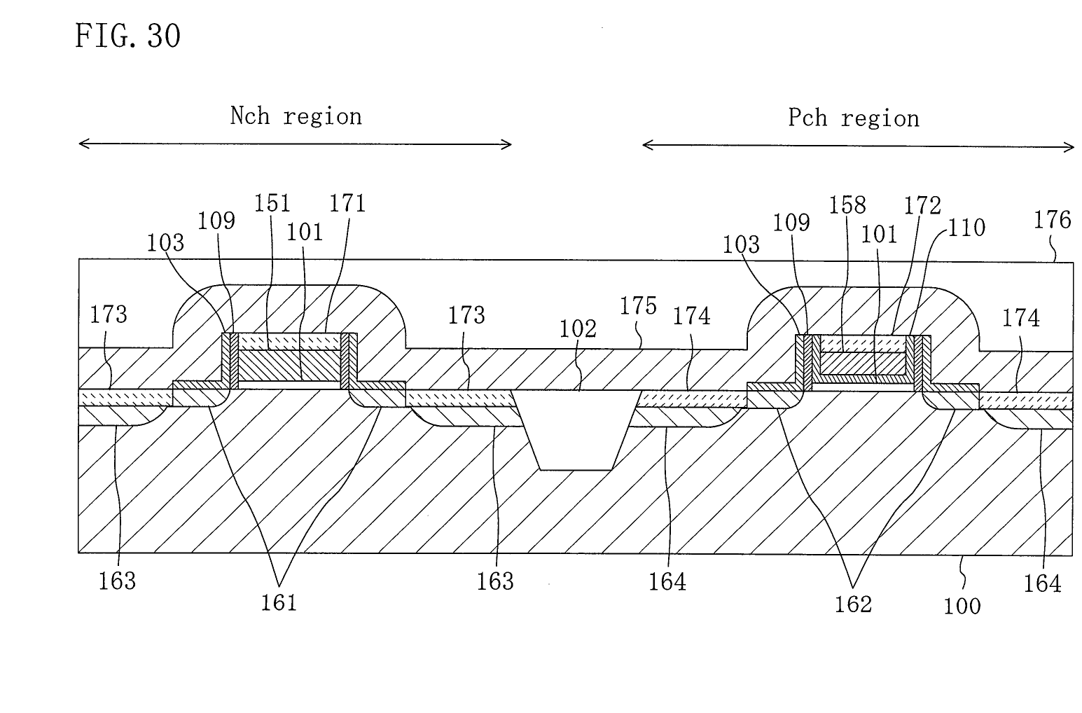

Note that the method for fabricating the semiconductor device according to the present variation of FIG. 29 is basically the same as that of the second variation of Embodiment 1 of FIGS. 24A and 24B and FIGS. 25A and 25B. Moreover, in fabricating the semiconductor device according to the present variation, after the insulating film 106 is removed, the sidewall nitride film 104 may be removed, and then the process of forming the silicide layers 171-174 and the process of forming the liner nitride film 175 and the interlayer insulating film 176 may be performed. In this case, it is possible to obtain a disposable sidewall structure as shown in FIG. 30.

### Embodiment 3

A semiconductor device according to Embodiment 3 of the present disclosure and a method for fabricating the same will be described below with reference to the drawings.

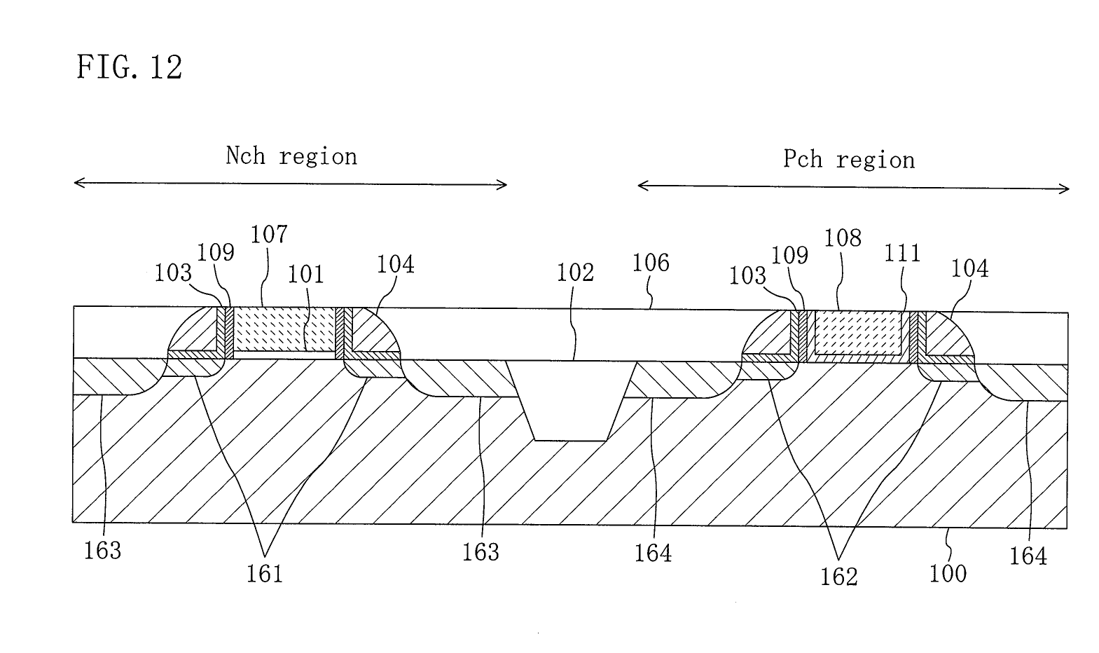

FIG. 12 is a cross-sectional view showing a structure of the semiconductor device according to Embodiment 3 of the present disclosure. Note that, in FIG. 12, the same reference characters as those of the semiconductor device according to Embodiment 1 of FIG. 1 are used to represent equivalent elements, and the same explanation thereof will be omitted.

The semiconductor device according to Embodiment 3 is different from the semiconductor device according to Embodiment 1 of FIG. 1 in the following points. That is, in Embodiment 1, as shown in FIG. 1, the same gate insulating film 101 made of, for example, a silicon oxide film is provided over the N-channel transistor region and the P-channel transistor region. By contrast, in Embodiment 3, a gate insulating film 101 (hereinafter referred to as a first gate insulating film 101) which is similar to that of Embodiment 1 is provided on an N-channel transistor region, and a second gate insulating film 111 including, for example, a radical oxide film having a thickness of about 1 nm and a hafnium silicon oxide film having a thickness of about 2 nm is provided on a P-channel transistor region. Note that the second gate insulating film 111 is formed not only between a second FUSI electrode 108 and the semiconductor substrate 101 but also between the second FUSI electrode 108 and offset spacers 109.

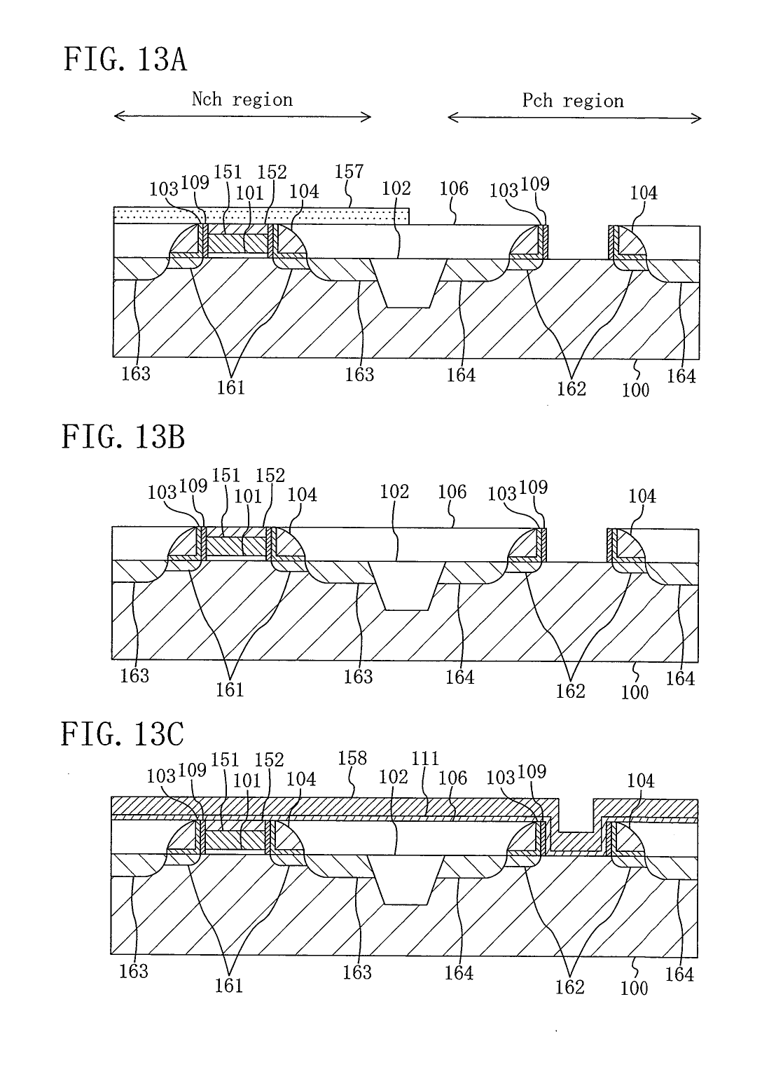

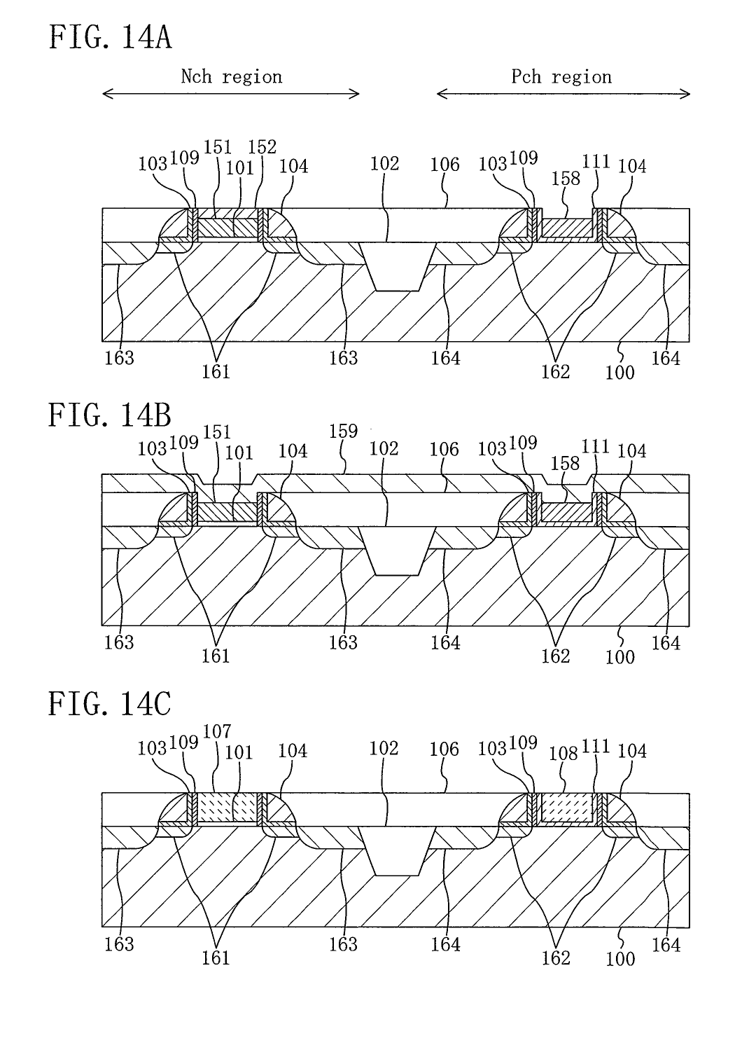

FIGS. 13A-13C, and FIGS. 14A-14C are cross-sectional views showing processes in the method for fabricating the semiconductor device according to Embodiment 3. Note that, in FIGS. 13A-13C, and FIGS. 14A-14C, the same reference characters as those shown in Embodiment 1 of FIGS. 2A-2C, FIGS. 3A-3C, FIGS. 4A-4C, FIGS. 5A-5C, FIGS. 6A-6C, FIGS. 7A-7C, and FIGS. 8A and 8B are used to represent equivalent elements, and the same explanation thereof will be omitted.

In the method for fabricating the semiconductor device according to Embodiment 3, first, the processes shown in FIGS. 2A-2C, FIGS. 3A-3C, FIGS. 4A-4C, FIGS. 5A-5C, and FIGS. 6A-6C in the method for fabricating the semiconductor device according to Embodiment 1 are sequentially performed.

Next, as shown in FIG. 13A, using the resist mask 157, the patterned first gate insulating film 101 over the P-channel transistor region is selectively removed by, for example, reactive ion etching. In this way, the surface of the semiconductor substrate 101 is exposed in the opening of the P-channel transistor region. The etching is performed, for example, under such conditions that the etching gas is a gas containing C₄F₈, the gas flow rate is 20 to 100 cc/min (standard condition), and the temperature is 20 to 50° C. After that, as shown in FIG. 13B, the resist mask 157 is removed by oxygen ashing.

Next, as shown in FIG. 13C, over the entire surface including the opening of the P-channel transistor region of the semiconductor substrate 100, a second gate insulating film 111 including, for example, a radical oxide film having a thickness of about 1 nm and a hafnium silicon oxide film having a thickness of about 2 nm is formed. Subsequently, on the entire surface of the second gate insulating film 111, a second silicon-containing material film 158 which is lower in density than the first silicon-containing material (polysilicon) film 151 is deposited. The second silicon-containing material film 158 is made of, for example, porous silicon or organic silicon, and has a thickness of about 30 to 100 nm. Details of a method for depositing the second silicon-containing material film 158 are similar to those of Embodiment 1 (the process shown in FIG. 7B).

Next, as shown in FIG. 14A, the second silicon-containing material film 158 and the second gate insulating film 111 deposited outside the opening of the P-channel transistor region are removed by, for example, chemical mechanical polishing. Next, as shown in FIG. 14B, the patterned hard mask film 152 over the N-channel transistor region is removed.

After that, over the entire surface of the semiconductor substrate 100, a metal film 159 such as a nickel film having a thickness of about 80 to 120 nm is formed by, for example, sputtering such that the metal film 159 is in contact with the patterned first silicon-containing material film 151 over the N-channel transistor region, and with the second silicon-containing material film 158 remaining in the opening of the P-channel transistor region.

Next, the semiconductor substrate 100 is subjected to a thermal treatment for silicidation so that the first silicon-containing material film 151 and the second silicon-containing material film 158 react with the metal film 159, thereby being fully silicided. After that, part of the metal film 159 which remains unreacted is selectively removed. As the thermal treatment for silicidation, for example, a process in which a RTP at a thermal treatment temperature of about 400 to 600° C. is performed in two steps is used. In this way, as shown in FIG. 14C, a first FUSI electrode 107 and a second FUSI electrode 108 are formed. After that, surfaces of the first FUSI electrode 107 and the second FUSI electrode 108 are planarized by, for example, chemical mechanical polishing.

According to Embodiment 3 described above, it is possible to achieve an effect similar to that of Embodiment 1. In Embodiment 1, the gate insulating film 101 is previously formed on the N-channel transistor region and the P-channel transistor region before forming the gate electrodes, which allows the process to be facilitated, but the gate insulating film 101 of the P-channel transistor region is inevitably damaged in removing the patterned first silicon-containing material film 151 over the P-channel transistor region to form the opening. By contrast, in Embodiment 3, the first gate insulating film 101 is removed and the second gate insulating film 111 is newly formed on the P-channel transistor region, so that it is possible to avoid the occurrence of the above-described problem and to improve the reliability of the transistor.

Note that, in Embodiment 3, as the second gate insulating film 111, a multilayer film including the radical oxide film and the hafnium silicon oxide film is used, but the second gate insulating film 111 is not particularly limited in terms of its insulating film material. Specifically, as the second gate insulating film 111, the following film may be used: a single-layer film made of an insulating film selected from an insulating film group consisting of a HfO₂ film, a HfAlₓO_{y} film, a HfSiₓO_{y} film (Zr may be added to the HfO₂ film, the HfAlₓO_{y} film, and the HfSiO_{y}), a film obtained by adding Zr to an SiO₂ film, a ZrO₂ and a film obtained by adding nitrogen to one of these films; or a multilayer insulating film including at least one insulating film selected from the insulating film group (the multilayer insulating film may include an insulating film (e.g., a silicon oxide film) other than the insulating films included in the insulating film group). As in the case of the present embodiment, when the second gate insulating film 111 includes a high-dielectric-constant insulating film (e.g., a hafnium silicon oxide film), it is possible to increase the physical thickness of gate insulating film while the equivalent oxide thickness thereof is reduced. Therefore, it is possible to increase the performance of the transistor while suppressing a leak current thereof.

Moreover, in Embodiment 3, the second gate insulating film 111 includes the high-dielectric-constant insulating film, but alternatively or additionally, the first gate insulating film 101 may include a high-dielectric-constant insulating film.

### First Variation of Embodiment 3

In Embodiment 3, the metal film 159 is deposited (FIG. 14B) at which time the insulating film 106 covering the source/drain regions 163 and 164 is not removed, so that surface portions of the source/drain regions 163 and 164 are not silicided. By contrast, in the present variation, the FUSI electrodes 107 and 108 are formed (FIG. 14C) after which time the removal of the insulating film 106, the deposition of a metal film for forming a silicide, a thermal treatment for silicidation, and the removal of unreacted metal are sequentially performed to form a silicide layer in the surface portions of the source/drain regions 163 and 164.

According to the present variation, it is possible to form a thin silicide layer on surfaces of the source/drain regions, which is an object of the FUSI gate process of fully siliciding the gate electrodes. Therefore, it is possible to form a shallower junction, which allows a so-called short channel effect to be suppressed.

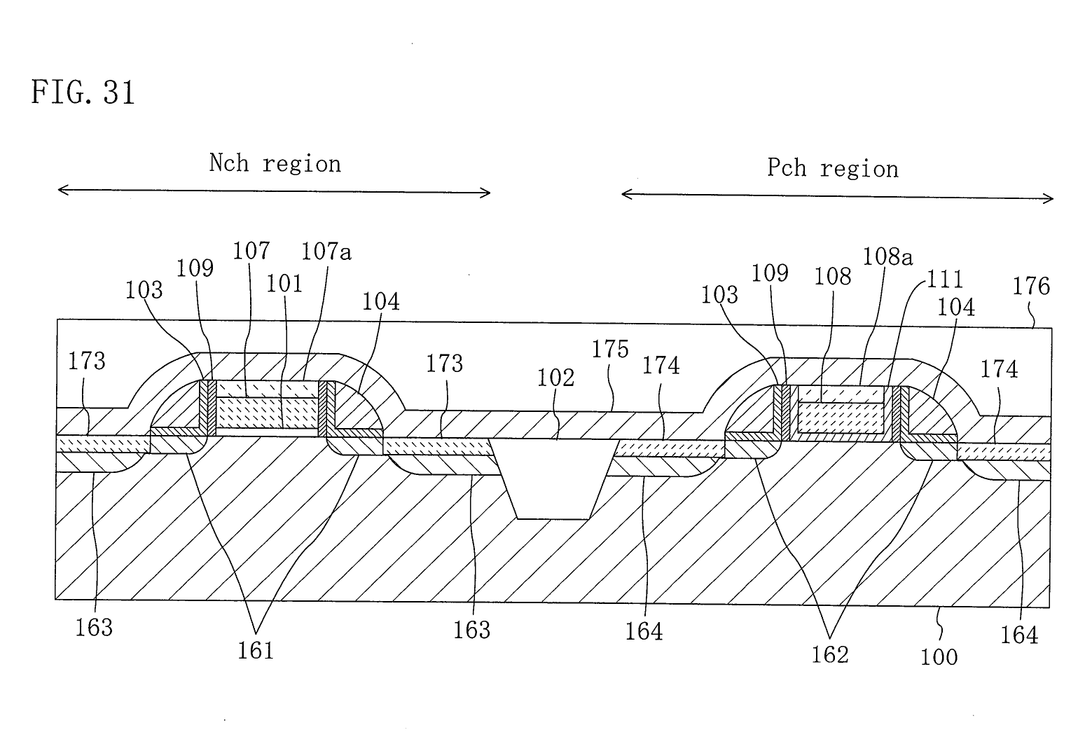

FIG. 31 is a cross-sectional view showing a structure of a semiconductor device according to the present variation. Note that, in FIG. 31, the same reference characters as those shown in Embodiment 3 of FIG. 12 are used to represent equivalent elements, and the same explanation thereof will be omitted.

The present variation is different from Embodiment 3 of FIG. 12 in the following points. For one thing, as shown in FIG. 31, a silicide layer 173 is provided in the surface portions of the source/drain regions 163, and a silicide layer 174 is provided in the surface portions of the source/drain regions 164. Note that, in the surface portions of the FUSI electrodes 107 and 108, re-silicide layers 107a and 108a are provided. Moreover, over the semiconductor substrate 100 including over the gate electrodes of the transistor regions, a liner nitride film 175 whose thickness or stress is sufficiently small or low so that no cracks occur is provided, and an interlayer insulating film 176 is provided on the liner nitride film 175.

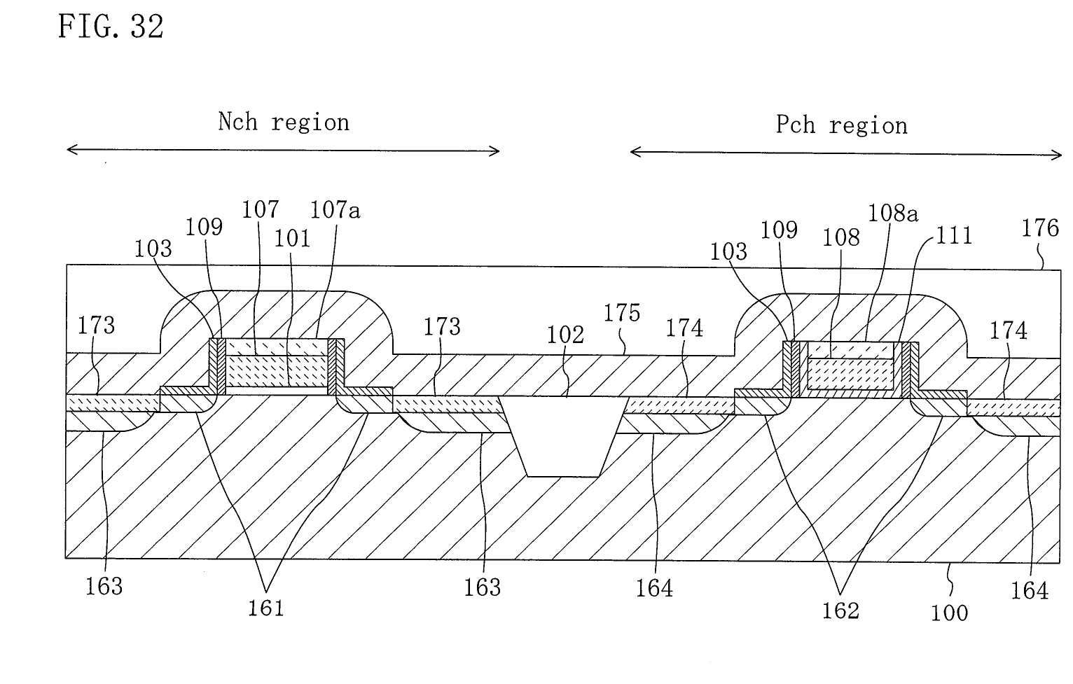

Note that the method for fabricating the semiconductor device according to the present variation of FIG. 31 is basically the same as that of the first variation of Embodiment 1 of FIGS. 20A and 20B, and FIG. 21. Moreover, in fabricating the semiconductor device according to the present variation, after the insulating film 106 is removed, the sidewall nitride film 104 may be removed, and then the process of forming the silicide layers 173 and 174 and the process of forming the liner nitride film 175 and the interlayer insulating film 176 may be performed. In this case, it is possible to obtain a disposable sidewall structure as shown in FIG. 32.

### Second Variation of Embodiment 3

In Embodiment 3, the metal film 159 is deposited (FIG. 14B) at which time the insulating film 106 covering the source/drain regions 163 and 164 is not removed. However, in the present variation, before depositing the metal film 159, the insulating film 106 is removed to form silicided electrodes using the metal film 159, and at the same time, to silicide the surface portions of the source/drain regions 163 and 164. In forming the silicided electrodes, gate electrodes may be fully silicided to form FUSI electrodes as in the case of Embodiment 3. However, an effect similar to that of Embodiment 3 can be achieved by siliciding only surface portion or surface portions of one or both of the gate electrodes of the N-channel transistor and the P-channel transistor. In other words, it may not be required to fully silicide the gate electrodes to achieve the effect similar to that of Embodiment 3. This configuration can be achieved by adjusting, for example, the thickness of the first silicon-containing material film 151 and the second silicon-containing material film 158, the material and the thickness of the metal film 159, and conditions for the thermal treatment for silicidation.

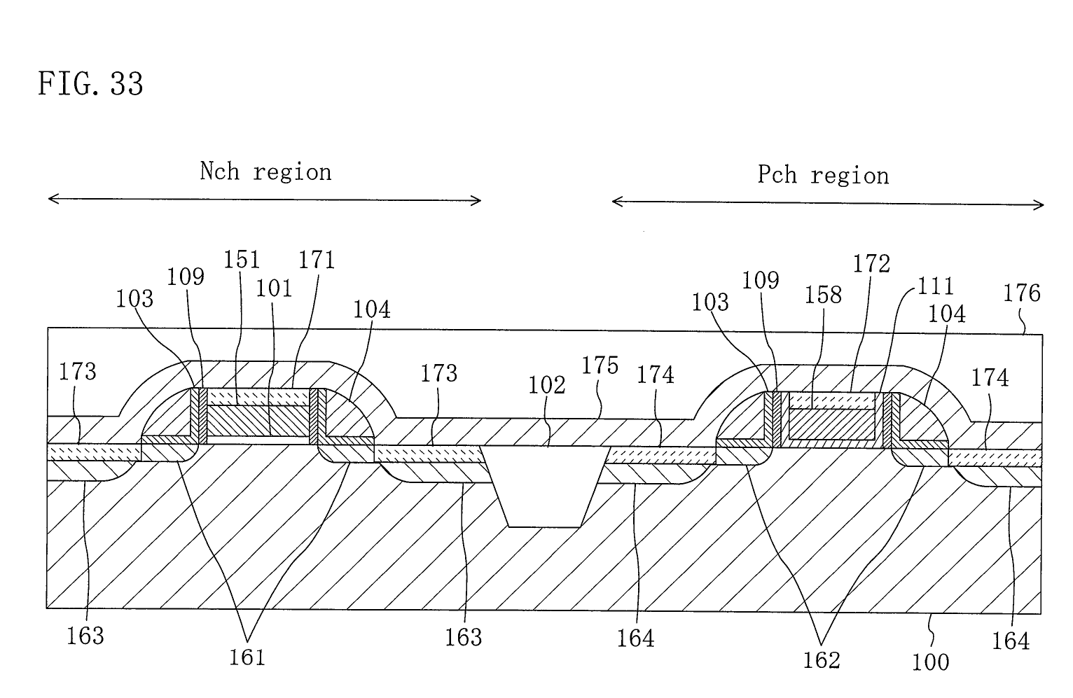

FIG. 33 is a cross-sectional view showing a structure of a semiconductor device according to the present variation. Note that, in FIG. 33, the same reference characters as those shown in Embodiment 3 of FIG. 12 are used to represent equivalent elements, and the same explanation thereof will be omitted.

The present variation is different from Embodiment 3 of FIG. 12 in the following points. For one thing, as shown in FIG. 33, instead of the first FUSI electrode 107 of the N-channel transistor region, a gate electrode including the first silicon-containing material film (silicon electrode part) 151 and a first silicide layer (silicided electrode part) 171 obtained by siliciding the first silicon-containing material film 151 is provided. Moreover, instead of the second FUSI electrode 108 of the P-channel transistor region, a gate electrode including the second silicon-containing material film (silicon electrode part) 158 and a second silicide layer (silicided electrode part) 172 obtained by siliciding the second silicon-containing material film 158 is provided.

Note that, as in the case of the above-described first variation, in the present variation, a silicide layer 173 is provided in the surface portions of the source/drain regions 163, and a silicide layer 174 is provided in the surface portions of the source/drain regions 164. Moreover, over the semiconductor substrate 100 including over the gate electrodes of the transistor regions, a liner nitride film 175 whose thickness or stress is sufficiently small or low so that no cracks occur is provided. An interlayer insulating film 176 is provided on the liner nitride film 175.

In the case of using no FUSI electrodes as in the case of the present variation, even if the liner nitride film 175 whose thickness or stress is sufficiently small or low so that no cracks occur is simultaneously used, that is, even if tensile stress by the liner nitride film 175 is caused in addition to tensile stress in the second silicon-containing material film 158 constituting the gate electrode, the tensile stress may not become excessive because the Young's modulus of the second silicon-containing material film 158 (e.g., organic silicon film) constituting the gate electrode of the P-channel transistor region is small.

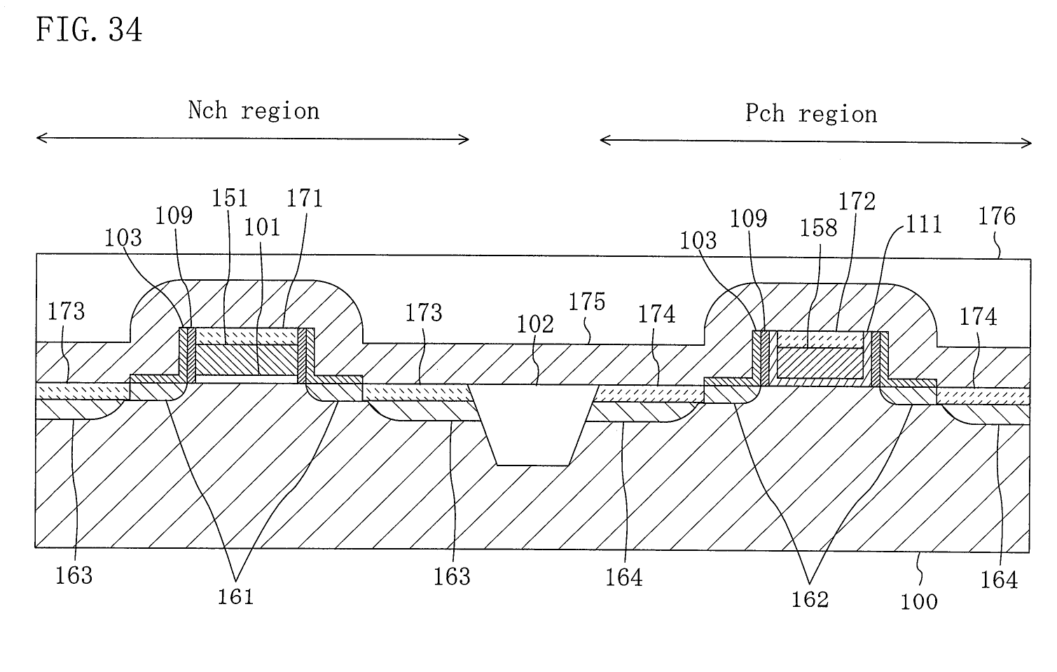

Note that the method for fabricating the semiconductor device according to the present variation of FIG. 33 is basically the same as that of the second variation of Embodiment 1 of FIGS. 24A and 24B and FIGS. 25A and 25B. Moreover, in fabricating the semiconductor device according to the present variation, after the insulating film 106 is removed, the sidewall nitride film 104 may be removed, and then the process of forming the silicide layers 171-174 and the process of forming the liner nitride film 175 and the interlayer insulating film 176 may be performed. In this case, it is possible to obtain a disposable sidewall structure as shown in FIG. 34.

### Embodiment 4

A semiconductor device according to Embodiment 4 of the present disclosure and a method for fabricating the same will be described below with reference to the drawings.

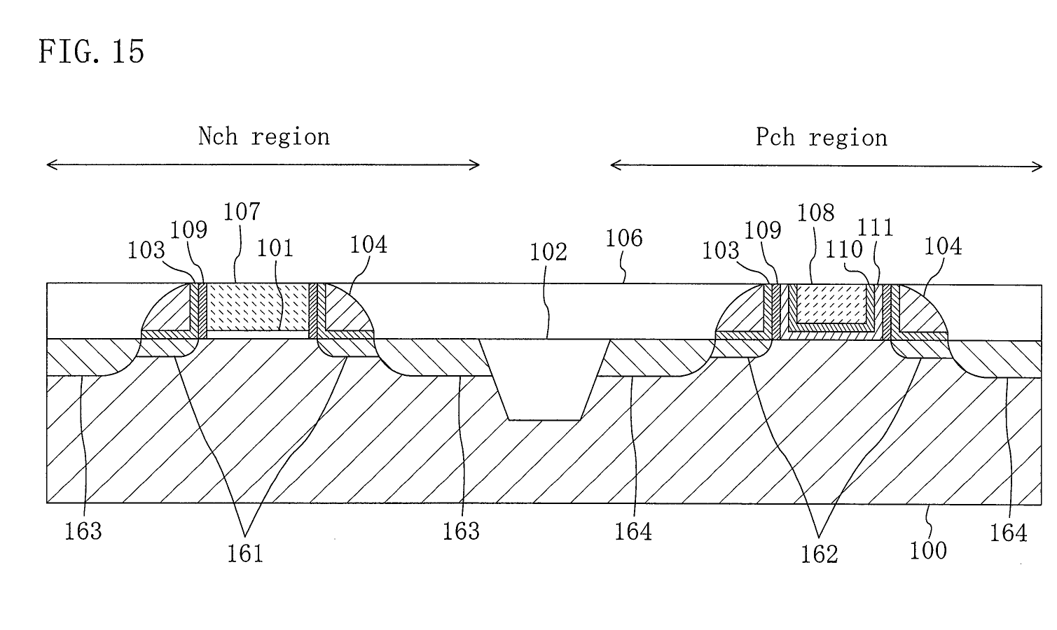

FIG. 15 is a cross-sectional view showing a structure of gate-electrode-formation regions of the semiconductor device according to Embodiment 4 of the present disclosure. Note that, in FIG. 15, the same reference characters as those of the semiconductor device according to Embodiment 1 of FIG. 1 are used to represent equivalent elements, and the same explanation thereof will be omitted.

As shown in FIG. 15, the first point in which the semiconductor device according to Embodiment 4 is different from the semiconductor device according to Embodiment 1 of FIG. 1 is as follows. That is, in Embodiment 1, as shown in FIG. 1, the same gate insulating film 101 made of, for example, a silicon oxide film is provided over the N-channel transistor region and the P-channel transistor region. By contrast, in Embodiment 4, a gate insulating film 101 (hereinafter referred to as a first gate insulating film 101) which is similar to that of Embodiment 1 is provided on an N-channel transistor region, and a second gate insulating film 111 including, for example, a radical oxide film having a thickness of about 1 nm and a hafnium silicon oxide film having a thickness of about 2 nm is provided on a P-channel transistor region. Note that the second gate insulating film 111 is formed not only between a second FUSI electrode 108 and the semiconductor substrate 101 but also between the second FUSI electrode 108 and offset spacers 109.

Moreover, as shown in FIG. 15, the second point in which the semiconductor device according to Embodiment 4 is different from the semiconductor device according to Embodiment 1 of FIG. 1 is that a metal layer 110 made of, for example, a TiN film having a thickness of about 5 to 15 nm is provided between the second FUSI electrode 108 of the P-channel transistor and the second gate insulating film 111. That is, in Embodiment 4, the gate electrode of the P-channel transistor has a multilayer structure including the second FUSI electrode 108 and the metal layer 110.

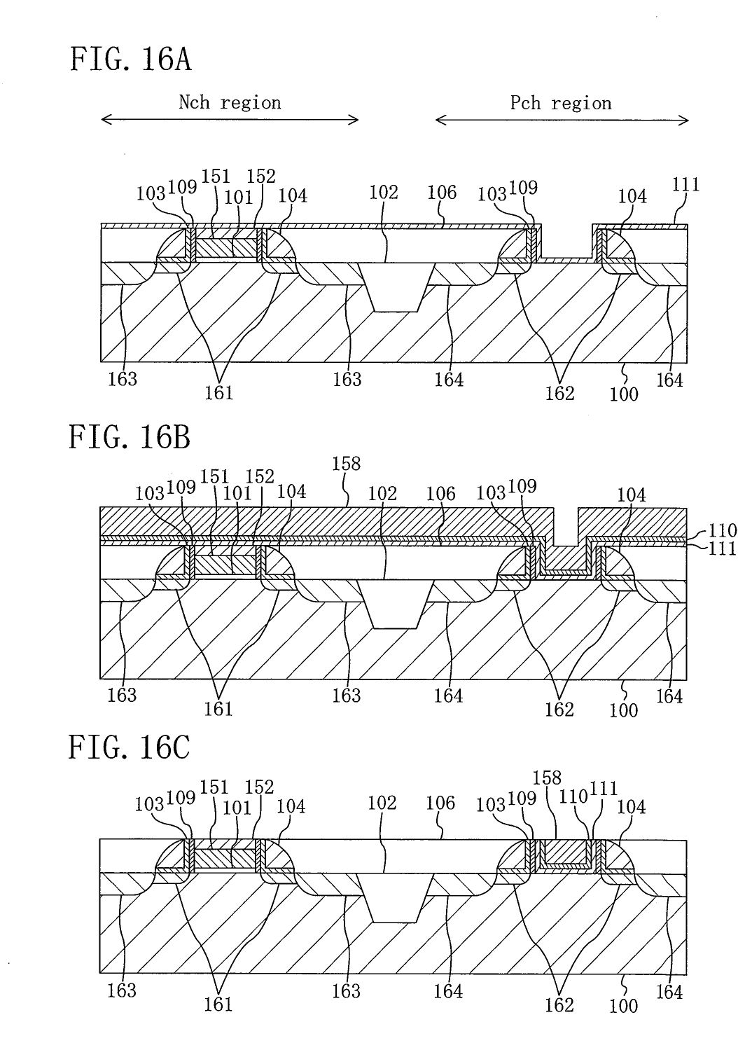

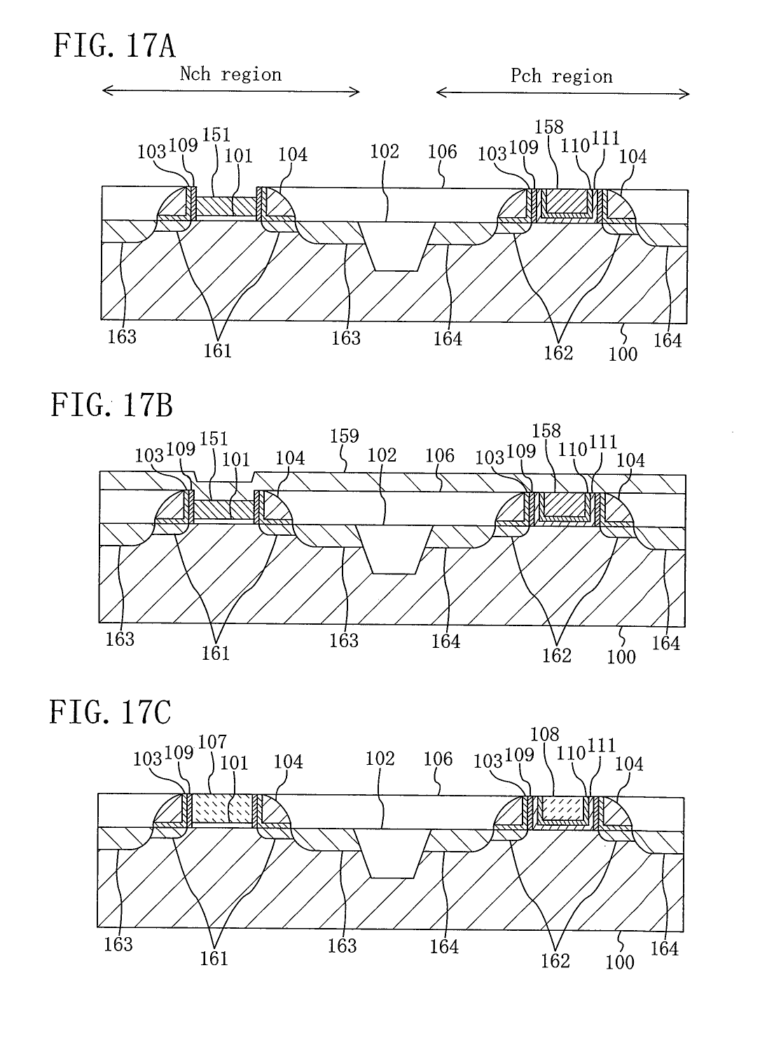

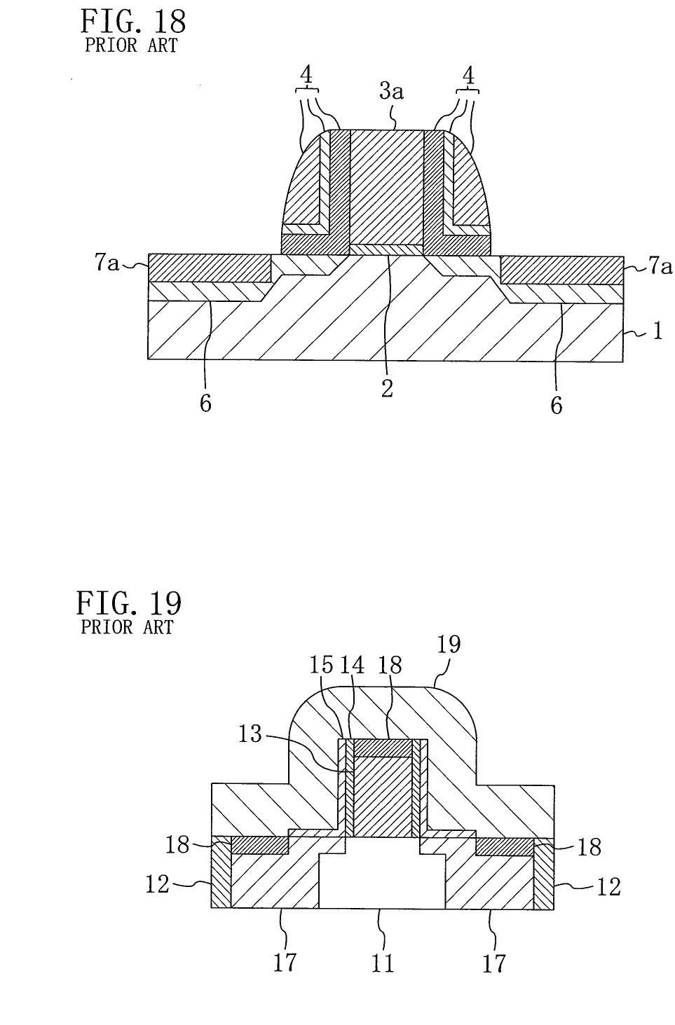

FIGS. 16A-16C, and FIGS. 17A-17C are cross-sectional views showing processes in the method for fabricating the semiconductor device according to Embodiment 4. Note that, in FIGS. 16A-16B, and FIGS. 17A-17C, the same reference characters as those shown in Embodiment 1 of FIGS. 2A-2C, FIGS. 3A-3C, FIGS. 4A-4C, FIGS. 5A-5C, FIGS. 6A-6C, FIGS. 7A-7C, and FIGS. 8A and 8B, in Embodiment 2 of FIGS. 10A-10C, and FIGS. 11A-11C, or in Embodiment 3 of FIGS. 13A-13C, and FIGS. 14A-14C are used to represent equivalent elements, and the same explanation thereof will be omitted.

In the method for fabricating the semiconductor device according to Embodiment 4, first, the processes shown in FIGS. 2A-2C, FIGS. 3A-3C, FIGS. 4A-4C, FIGS. 5A-5C, and FIGS. 6A-6C in the method for fabricating the semiconductor device according to Embodiment 1 are sequentially performed.

Next, the processes in the method for fabricating the semiconductor device according to Embodiment 3 shown in FIGS. 13A and 13B are sequentially performed.

Next, as shown in FIG. 16A, over the entire surface including the opening of the P-channel transistor region of the semiconductor substrate 100, a second gate insulating film 111 including, for example, a radical oxide film having a thickness of about 1 nm and a hafnium silicon oxide film having a thickness of about 2 nm is formed.

Next, as shown in FIG. 16B, on the entire surface of the second gate insulating film 111, a metal layer 110 which is, for example, a TiN film having a thickness of about 5 to 15 nm is formed. Then, on the entire surface of the metal layer 110, a second silicon-containing material film 158 which is lower in density than the first silicon-containing material (polysilicon) film 151 is deposited. The second silicon-containing material film 158 is made of, for example, porous silicon or organic silicon, and has a thickness of about 30 to 100 nm. Details of a method for depositing the second silicon-containing material film 158 are similar to those of Embodiment 1 (the process shown in FIG. 7B).

Next, as shown in FIG. 16C, the second silicon-containing material film 158, the metal layer 110, and the second gate insulating film 111 deposited outside the opening of the P-channel transistor region are removed by, for example, chemical mechanical polishing. Next, as shown in FIG. 17A, the patterned hard mask film 152 over the N-channel transistor region is removed. After that, as shown in FIG. 17B, over the entire surface of the semiconductor substrate 100, a metal film 159 such as a nickel film having a thickness of about 80 to 120 nm is formed by, for example, sputtering such that the metal film 159 is in contact with the patterned first silicon-containing material film 151 over the N-channel transistor region, and with the second silicon-containing material film 158 remaining in the opening of the P-channel transistor region.

Next, the semiconductor substrate 100 is subjected to a thermal treatment for silicidation so that the first silicon-containing material film 151 and the second silicon-containing material film 158 react with the metal film 159, thereby being fully silicided. After that, part of the metal film 159 which remains unreacted is selectively removed. As the thermal treatment for silicidation, for example, a process in which a RTP at a thermal treatment temperature of about 400 to 600° C. is performed in two steps is used. In this way, as shown in FIG. 17C, a first FUSI electrode 107 and a second FUSI electrode 108 are formed. After that, surfaces of the first FUSI electrode 107 and the second FUSI electrode 108 are planarized by, for example, chemical mechanical polishing.

According to Embodiment 4 described above, it is possible to achieve an effect similar to that of Embodiment 1. In Embodiment 1, the gate insulating film 101 is previously formed on the N-channel transistor region and the P-channel transistor region before forming the gate electrodes, which allows the process to be facilitated, but the gate insulating film 101 of the P-channel transistor region is inevitably damaged in removing the patterned first silicon-containing material film 151 over the P-channel transistor region to form the opening. By contrast, in Embodiment 4, the first gate insulating film 101 is removed and the second gate insulating film 111 is newly formed on the P-channel transistor region, so that it is possible to avoid the occurrence of the above-described problem and to improve the reliability of the transistor.

Moreover, according to Embodiment 4, the gate electrode of the P-channel transistor includes the metal layer 110 formed between the second FUSI electrode 108 and the gate insulating film 101, so that it is possible to achieve the effect that the threshold voltage (Vt) of the P-channel transistor can be controlled easily.

Note that, in Embodiment 4, as the second gate insulating film 111, a multilayer film including the radical oxide film and the hafnium silicon oxide film is used, but the second gate insulating film 111 is not particularly limited in terms of its insulating film material. Specifically, as the second gate insulating film 111, the following film may be used: a single-layer film made of an insulating film selected from an insulating film group consisting of a HfO₂ film, a HfAlₓO_{y} film, a HfSiₓO_{y} film (Zr may be added to the HfO₂ film, the HfAlₓO_{y} film, and the HfSiₓO_{y}), a film obtained by adding Zr to an SiO₂ film, a ZrO₂ film, and a film obtained by adding nitrogen to one of these films; or a multilayer insulating film including at least one insulating film selected from the insulating film group (the multilayer insulating film may include an insulating film (e.g., a silicon oxide film) other than the insulating films included in the insulating film group). As in the case of the present embodiment, when the second gate insulating film 111 includes a high-dielectric-constant insulating film (e.g., a hafnium silicon oxide film), it is possible to increase the physical thickness of gate insulating film while the equivalent oxide thickness thereof is reduced. Therefore, it is possible to increase the performance of the transistor while suppressing a leak current thereof.

Moreover, in Embodiment 4, the second gate insulating film 111 includes the high-dielectric-constant insulating film, but alternatively or additionally, the first gate insulating film 101 may include a high-dielectric-constant insulating film.

Moreover, in Embodiment 4, TiN is used as a material for the metal layer 110, but instead of TiN, other metal materials having, for example, a work function (W) of 4.7 eV or larger may be used. Specifically, the following film may be used: a single-layer film which is a metal film made of at least one metal (or which is an alloy film when two or more metals are) selected from a metal group consisting of Ni, Pd, Pt, Co, Rh, Ru, Cu, Ag, Au, Ti, Zr, Hf, V, Nb, Ta, Cr, Mo, and W; a single-layer film made of a silicide, a carbide, or a nitride of at least one metal selected from the metal group above; or a multilayer film including these metal films (including the case where the metals are silicided, carbonized, or nitrided).

Moreover, in Embodiment 4, the gate electrode of the P-channel transistor includes the metal layer 110 formed between the second FUSI electrode 108 and the second gate insulating film 111, but alternatively or additionally, the gate electrode of the N-channel transistor may have a metal layer formed between the first FUSI electrode 107 and the first gate insulating film 101.

### First Variation of Embodiment 4

In Embodiment 4, the metal film 159 is deposited (FIG. 17B) at which time the insulating film 106 covering the source/drain regions 163 and 164 is not removed, so that surface portions of the source/drain regions 163 and 164 are not silicided. By contrast, in the present variation, the FUSI electrodes 107 and 108 are formed (FIG. 17C) after which time the removal of the insulating film 106, the deposition of a metal film for forming a silicide, a thermal treatment for silicidation, and the removal of unreacted metal are sequentially performed to form a silicide layer in the surface portions of the source/drain regions 163 and 164.

According to the present variation, it is possible to form a thin silicide layer on surfaces of the source/drain regions, which is an object of the FUSI gate process of fully siliciding the gate electrodes. Therefore, it is possible to form a shallower junction, which allows a so-called short channel effect to be suppressed.

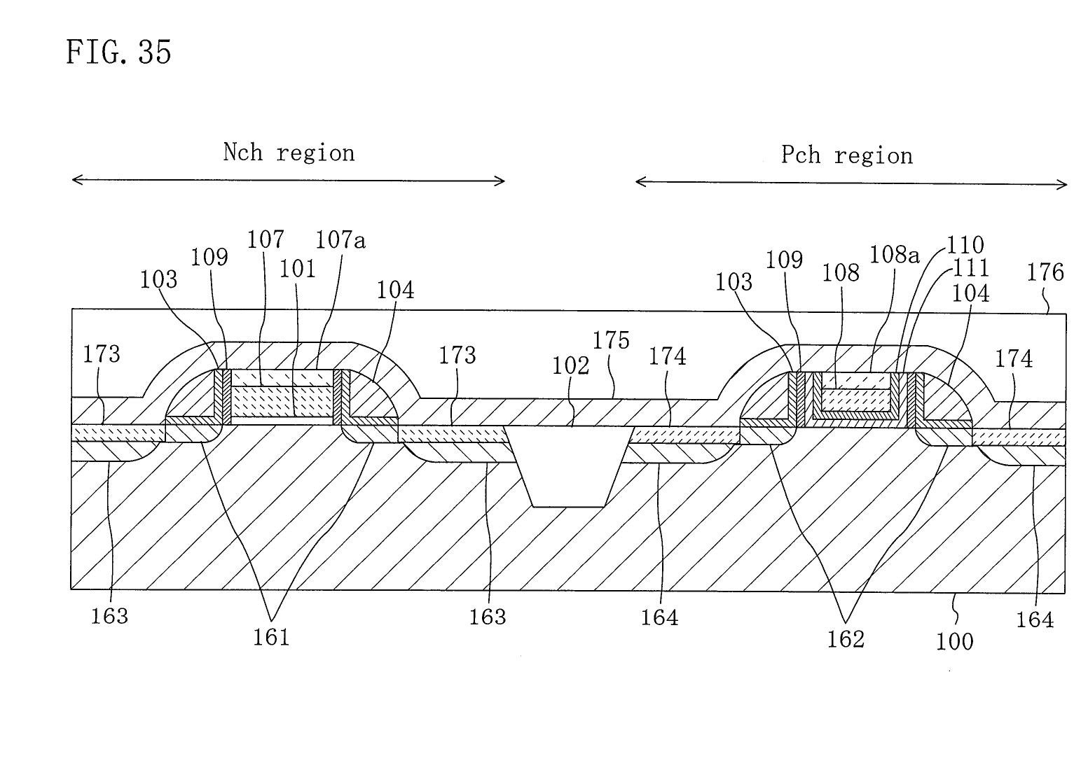

FIG. 35 is a cross-sectional view showing a structure of a semiconductor device according to the present variation. Note that, in FIG. 35, the same reference characters as those shown in Embodiment 4 of FIG. 15 are used to represent equivalent elements, and the same explanation thereof will be omitted.

The present variation is different from Embodiment 4 of FIG. 15 in the following points. For one thing, as shown in FIG. 35, a silicide layer 173 is provided in the surface portions of the source/drain regions 163, and a silicide layer 174 is provided in the surface portions of the source/drain regions 164. Note that, in the surface portions of the FUSI electrodes 107 and 108, re-silicide layers 107a and 108a are provided. Moreover, over the semiconductor substrate 100 including over the gate electrodes of the transistor regions, a liner nitride film 175 whose thickness or stress is sufficiently small or low so that no cracks occur is provided, and an interlayer insulating film 176 is provided on the liner nitride film 175.

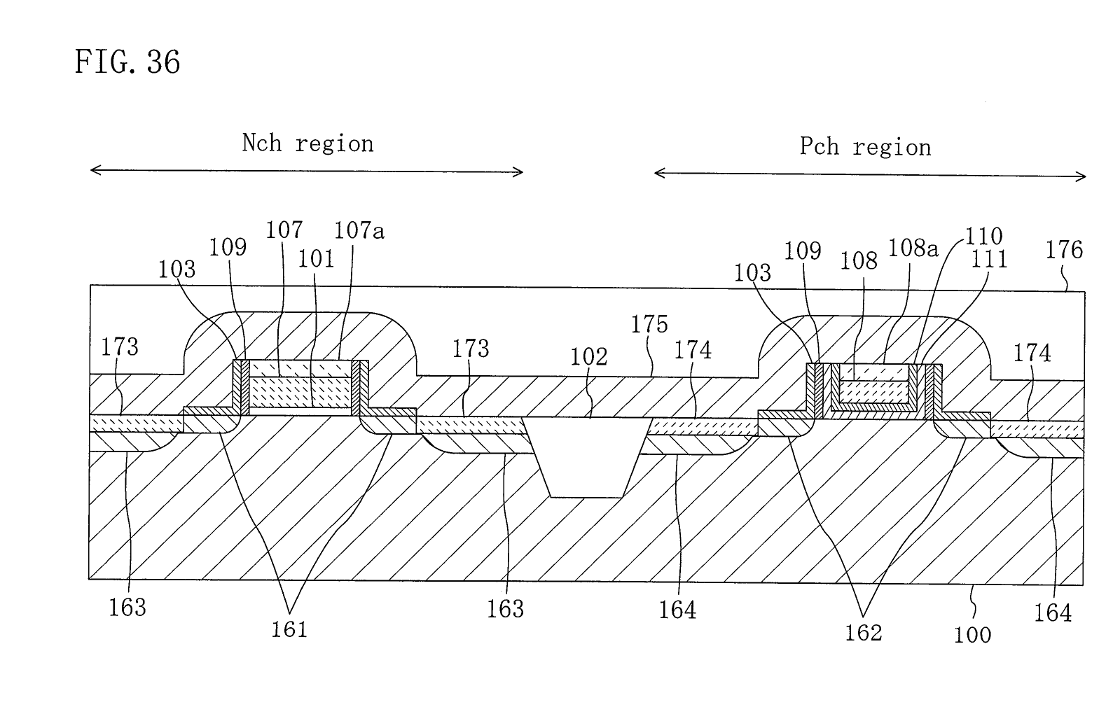

Note that the method for fabricating the semiconductor device according to the present variation of FIG. 35 is basically the same as that of the first variation of Embodiment 1 of FIGS. 20A and 20B, and FIG. 21. Moreover, in fabricating the semiconductor device according to the present variation, after the insulating film 106 is removed, the sidewall nitride film 104 may be removed, and then the process of forming the silicide layers 173 and 174 and the process of forming the liner nitride film 175 and the interlayer insulating film 176 may be performed. In this case, it is possible to obtain a disposable sidewall structure as shown in FIG. 36.

### Second Variation of Embodiment 4

In Embodiment 4, the metal film 159 is deposited (FIG. 17B) at which time the insulating film 106 covering the source/drain regions 163 and 164 is not removed. However, in the present variation, before depositing the metal film 159, the insulating film 106 is removed to form silicided electrodes using the metal film 159, and at the same time, to silicide the surface portions of the source/drain regions 163 and 164. In forming the silicided electrodes, gate electrodes may be fully silicided to form FUSI electrodes as in the case of Embodiment 4. However, an effect similar to that of Embodiment 4 can be achieved by siliciding only surface portion or surface portions of one or both of the gate electrodes of the N-channel transistor and the P-channel transistor. In other words, it may not be required to fully silicide the gate electrodes to achieve the effect similar to that of Embodiment 4. This configuration can be achieved by adjusting, for example, the thickness of the first silicon-containing material film 151 and the second silicon-containing material film 158, the material and the thickness of the metal film 159, and conditions for the thermal treatment for silicidation.

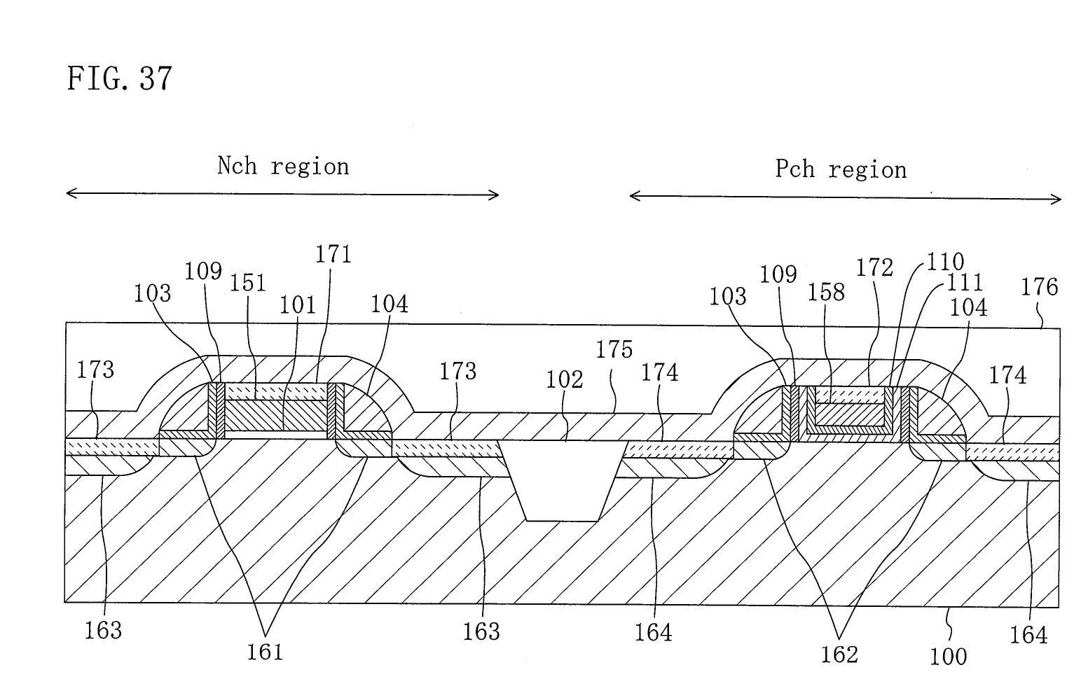

FIG. 37 is a cross-sectional view showing a structure of a semiconductor device according to the present variation. Note that, in FIG. 37, the same reference characters as those shown in Embodiment 4 of FIG. 15 are used to represent equivalent elements, and the same explanation thereof will be omitted.

The present variation is different from Embodiment 4 of FIG. 15 in the following points. For one thing, as shown in FIG. 37, instead of the first FUSI electrode 107 of the N-channel transistor region, a gate electrode including the first silicon-containing material film (silicon electrode part) 151 and a first silicide layer (silicided electrode part) 171 obtained by siliciding the first silicon-containing material film 151 is provided. Moreover, instead of the second FUSI electrode 108 of the P-channel transistor region, a gate electrode including the second silicon-containing material film (silicon electrode part) 158 and a second silicide layer (silicided electrode part) 172 obtained by siliciding the second silicon-containing material film 158 is provided. Note that the gate electrode of the P-channel transistor region further includes a metal layer 110 disposed between the second silicon-containing material film (silicon electrode part) 158 and the second gate insulating film 111.

Note that, as in the case of the above-described first variation, in the present variation, a silicide layer 173 is provided in the surface portions of the source/drain regions 163, and a silicide layer 174 is provided in the surface portions of the source/drain regions 164. Moreover, over the semiconductor substrate 100 including the gate electrodes of the transistor regions, a liner nitride film 175 whose thickness or stress is sufficiently small or low so that no cracks occur is provided. An interlayer insulating film 176 is provided on the liner nitride film 175.

In the case of using no FUSI electrodes as in the case of the present variation, even if the liner nitride film 175 whose thickness or stress is sufficiently small or low so that no cracks occur is simultaneously used, that is, even if tensile stress by the liner nitride film 175 is caused in addition to tensile stress in the second silicon-containing material film 158 constituting the gate electrode, the tensile stress may not become excessive because the Young's modulus of the second silicon-containing material film 158 (e.g., organic silicon film) constituting the gate electrode of the P-channel transistor region is small.

Moreover, even if no FUSI electrodes are used as in the case of the present variation, it is possible to suppress depletion of the gate electrode of the P-channel transistor because the gate electrode of the P-channel transistor further includes the metal layer 110 disposed between the second silicon-containing material film (silicon electrode part) 158 and the second gate insulating film 111. Therefore, an ON current of the P-channel transistor can be increased, which enables the operating speed of the integrated circuit to be improved. Moreover, it is of course possible to obtain similar advantages for the gate electrode of the N-channel transistor by disposing a metal layer between the first silicon-containing material film (silicon electrode part) 151 and the first gate insulating film 101.

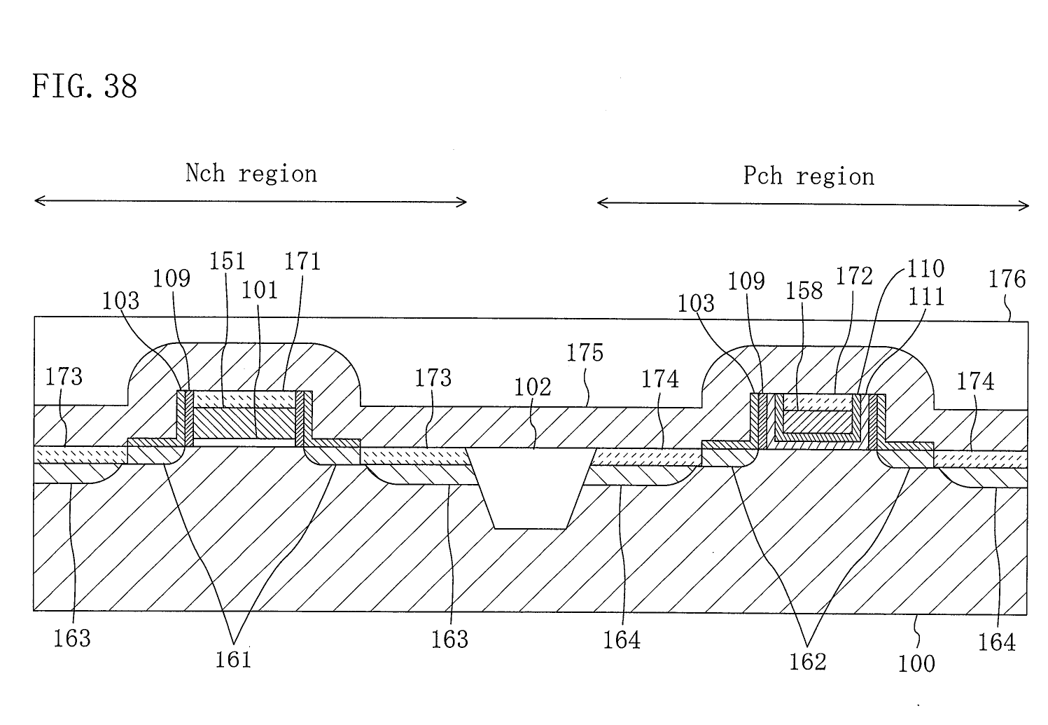

Note that the method for fabricating the semiconductor device according to the present variation of FIG. 37 is basically the same as that of the second variation of Embodiment 1 of FIGS. 24A and 24B and FIGS. 25A and 25B. Moreover, in fabricating the semiconductor device according to the present variation, after the insulating film 106 is removed, the sidewall nitride film 104 may be removed, and then the process of forming the silicide layers 171-174 and the process of forming the liner nitride film 175 and the interlayer insulating film 176 may be performed. In this case, it is possible to obtain a disposable sidewall structure as shown in FIG. 38.

The present disclosure relates to semiconductor devices and methods for fabricating the same in which volume expansion during silicidation of the gate electrode of the P-channel transistor is selectively suppressed, so that stress in the gate electrode can be controlled, which can improve the performance of the transistor by controlling the stress even in the case of miniaturizing the device. Thus, the present disclosure is very useful.

What is claimed is:

1. A semiconductor device comprising a gate electrode including a silicide layer obtained by siliciding porous silicon or organic silicon.

2. A semiconductor device comprising:
an N-channel transistor; and
a P-channel transistor, wherein
the N-channel transistor includes a first gate electrode having a first silicide layer,
the P-channel transistor includes a second gate electrode having a second silicide layer,
the first silicide layer is formed by siliciding a first silicon-containing material,
the second silicide layer is formed by siliciding a second silicon-containing material which is different from the first silicon-containing material, and
a density of the second silicon-containing material is smaller than a density of the first silicon-containing material.

3. The semiconductor device of claim 2, wherein
the first silicon-containing material is silicon, and
the second silicon-containing material is porous silicon or organic silicon.

4. A method for fabricating a semiconductor device including a first transistor including a first gate electrode having a first silicide layer, and a second transistor including a second gate electrode having a second silicide layer, the method comprising:
(a) forming an insulative isolation region on a semiconductor substrate to separate a first transistor region from a second transistor region;
(b) forming a first silicon-containing material film over the semiconductor substrate, and then patterning the first silicon-containing material film over each of the first transistor region and the second transistor region into a gate electrode form;
(c) forming an insulating film over the semiconductor substrate to cover all parts except an upper surface of the patterned first silicon-containing material film,
(d) removing the patterned first silicon-containing material film over the second transistor region to form an opening;
(e) in the opening, forming a second silicon-containing material film which has a density different from a density of the first silicon-containing material film; and
(f) siliciding the patterned first silicon-containing material film over the first transistor region to form the first silicide layer, and siliciding the second silicon-containing material film formed in the opening to form the second silicide layer.

5. The method of claim 4, wherein
the first transistor is an N-channel transistor,
the second transistor is a P-channel transistor, and
the density of the second silicon-containing material film is smaller than the density of the first silicon-containing material film.

6. The method of claim 5, wherein
the first silicon-containing material film is made of silicon, and
the second silicon-containing material film is made of porous silicon or organic silicon.

7. The method of claim 4, wherein
the first transistor is a P-channel transistor,
the second transistor is an N-channel transistor, and
the density of the first silicon-containing material film is smaller than the density of the second silicon-containing material film.

8. The method of claim 7, wherein
the first silicon-containing material film is made of porous silicon or organic silicon, and
the second silicon-containing material film is made of silicon.

9. The method of claim 4, wherein
the second gate electrode includes a metal layer formed under the second silicide layer, and
the method further includes, between (d) and (e), (g) forming the metal layer at least at a bottom of the opening.

10. The method of claim 4, wherein
the first transistor includes a first gate insulating film under the first gate electrode,
the second transistor includes a second gate insulating film under the second gate electrode, and
the method further includes, between (a) and (b), (h) forming the first gate insulating film and the second gate insulating film.

11. The method of claim 4, wherein
the first transistor includes a first gate insulating film under the first gate electrode,
the second transistor includes a second gate insulating film under the second gate electrode,
the method further includes, between (a) and (b), (i) forming the first gate insulating film, and includes, between (d) and (e), (j) forming the second gate insulating film at least at a bottom of the opening.

12. The method of claim 11, wherein
the second gate electrode includes a metal layer formed under the second silicide layer, and
the method further includes, between (j) and (e), (k) forming the metal layer on the second gate insulating film in the opening.

13. The method of claim 10, wherein at least one of the first gate insulating film and the second gate insulating film includes a high-dielectric-constant insulating film.

14. The method of claim 11, wherein at least one of the first gate insulating film and the second gate insulating film includes a high-dielectric-constant insulating film.

15. The method of claim 12, wherein at least one of the first gate insulating film and the second gate insulating film includes a high-dielectric-constant insulating film.

16. A semiconductor device comprising a gate electrode, wherein
the gate electrode includes
a silicon layer made of porous silicon or organic silicon, and
a silicide layer formed on the silicon layer.

17. The semiconductor device of claim 16, wherein the gate electrode further includes a metal layer formed under the silicon layer.

18. A semiconductor device comprising a gate electrode, wherein the gate electrode includes a silicide layer containing an organic substance.
